(19) United States
(12) Patent Application Publication
(10) Pub. No.: US 2024/0312914 A1
(43) Pub. Date: Sep. 19, 2024

(54) SEMICONDUCTOR DEVICE WITH LOWER CONTACT AND LOWER POWER STRUCTURE AND METHOD OF MANUFACTURING THE SAME

(71) Applicant: SAMSUNG ELECTRONICS CO, LTD., Suwon-si (KR)

(72) Inventors: JEONGYEON SEO, Suwon-si (KR); DONG KWON KIM, Suwon-si (KR); HYONWOOK RA, Suwon-si (KR); HONGSIK SHIN, Suwon-si (KR)

(73) Assignee: SAMSUNG ELECTRONICS CO, LTD, Suwon-si (KR)

(21) Appl. No.: 18/370,263

(22) Filed: Sep. 19, 2023

(30) Foreign Application Priority Data
Mar. 17, 2023 (KR) 10-2023-0035437

(51) Int. Cl. H01L 23/528; H01L 21/768; H01L 23/48; H01L 23/522

(52) U.S. Cl. CPC H01L 23/5286; H01L 21/76805; H01L 21/76898; H01L 23/481; H01L 23/5226; H01L 27/092

(57) ABSTRACT

Disclosed are a semiconductor device and a method of manufacturing the same. The semiconductor device may include: a substrate comprising an active pattern; a source/drain pattern on the active pattern; a device isolation layer at a lateral side of the active pattern; a lower power structure below a top surface of the substrate; a lower contact penetrating the device isolation layer and connecting the source/drain pattern to the lower power structure; and a power delivery network layer below the top surface of the substrate, wherein the lower power structure comprises a connecting portion connected to the lower contact, and wherein the lower contact comprises a protruding portion buried in the connecting portion.

### CROSS-REFERENCE TO RELATED APPLICATIONS

This application claims priority under 35 U.S.C. § 119 to Korean Patent Application No. 10-2023-0035437, filed on Mar. 17, 2023, in the Korean Intellectual Property Office, the entire disclosure of which is incorporated herein by reference.

### BACKGROUND

The present disclosure relates to a semiconductor device and a method of manufacturing the same, and in particular, to a semiconductor device including a field-effect transistor and a method of manufacturing the same.

A semiconductor device forming an integrated circuit includes a plurality of metal-oxide-semiconductor field-effect transistors (MOSFETs). To meet an increasing demand for a semiconductor device having a high device density, the MOSFETs are being aggressively scaled down, which may lead to deterioration in operational properties of the semiconductor device. A variety of studies are being conducted to overcome technical limitations for the scaled down semiconductor device and to realize high-performance semiconductor devices.

### SUMMARY

Various embodiments of the present disclosure provide a semiconductor device with improved electrical and reliability characteristics.

The embodiments also provide a method of manufacturing a semiconductor device with improved electrical and reliability characteristics.

According to an embodiment, there is provided a semiconductor device which may include: a substrate comprising an active pattern; a source/drain pattern on the active pattern; a device isolation layer at a lateral side of the active pattern; a lower power structure below a top surface of the substrate; a lower contact penetrating the device isolation layer and connecting the source/drain pattern to the lower power structure; and a power delivery network layer below the top surface of the substrate, wherein the lower power structure comprises a connecting portion connected to the lower contact, and wherein the lower contact comprises a protruding portion buried in the connecting portion.

According to an embodiment, there is provided a method of manufacturing a semiconductor device. The method may include: forming an active pattern on a substrate; forming a device isolation layer at a side of the active pattern; forming a source/drain pattern on the active pattern, and a interlayer insulating layer on the source/drain pattern; forming a contact hole, which is vertically extended from the interlayer insulating layer to the substrate to expose an inner side surface of the substrate; oxidizing the inner side surface of the substrate to form a protective capping pattern; filling the contact hole with a metallic material to form a lower contact; performing a patterning process on a bottom surface of the substrate to form an interconnection trench exposing the lower contact; removing the protective capping pattern; and filling the interconnection trench with a conductive material to form a lower power structure

According to an embodiment, there is provided a semiconductor device which may include: a substrate comprising an active pattern; a device isolation layer at a lateral side of the active pattern; a source/drain pattern on the active pattern; an interlayer insulating layer isolating the source/drain pattern; an active contact connected to the source/drain pattern; a lower power structure in the substrate; a lower contact and extended into the substrate at a lateral side of the source/drain pattern, the lower contact connecting the active contact to the lower power structure; and a power delivery network layer below a top surface of the substrate, wherein the lower contact comprises a lower portion inserted in the lower power structure.

### BRIEF DESCRIPTION OF DRAWINGS

FIGS. 1 to 3 are conceptual diagrams illustrating logic cells in a semiconductor device according to an embodiment.

FIG. 4 is a plan view illustrating a semiconductor device according to an embodiment.

FIGS. 5A to 5E are sectional views taken along lines A-A′, B-B′, C-C′, D-D′, and E-E′ of FIG. 4, respectively.

FIG. 6 is an enlarged sectional view illustrating a portion ‘M’ of FIG. 5D.

FIGS. 7A and 7B to 19 are sectional views illustrating a method of manufacturing a semiconductor device according to an embodiment.

FIGS. 20A and 20B are sectional views, which are taken along lines C-C′ and F-F′ of FIG. 4 to illustrate a semiconductor device according to an embodiment.

### DETAILED DESCRIPTION

The embodiments described herein are non-limiting example embodiments, and thus, the disclosure is not limited thereto and may be realized in various other forms.

It will be understood that when an element or layer is referred to as being “over,” “above,” “on,” “below,” “under,” “beneath,” “connected to” or “coupled to” another element or layer, it can be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

As used herein, an expression “at least one of” preceding a list of elements modifies the entire list of the elements and does not modify the individual elements of the list. For example, an expression, “at least one of a, b, and c” should be understood as including only a, only b, only c, both a and b, both a and c, both b and c, or all of a, b, and c.

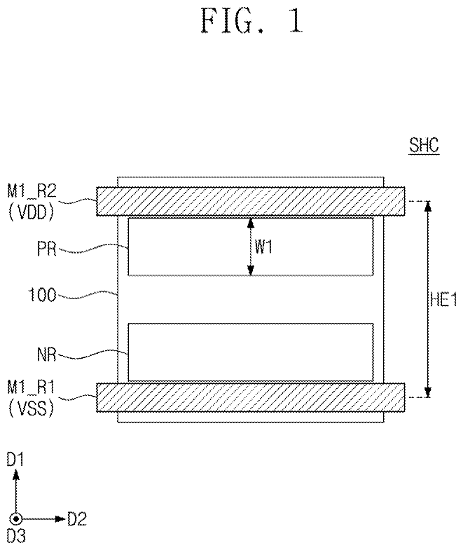

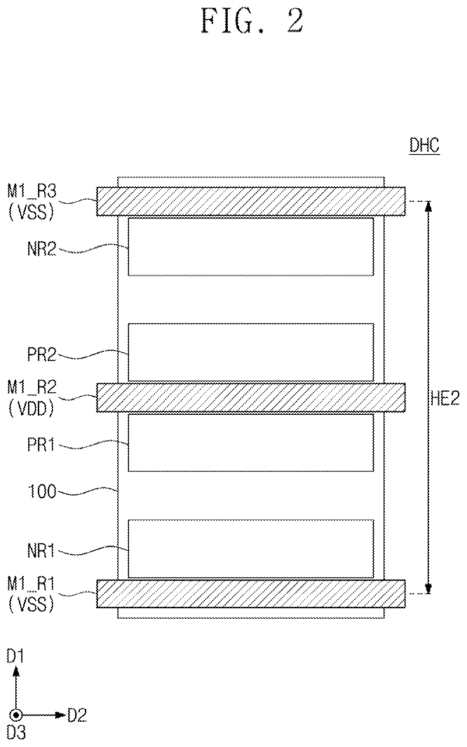

FIGS. 1 to 3 are conceptual diagrams illustrating logic cells in a semiconductor device according to an embodiment.

Referring to FIG. 1, a single height cell SHC may be provided. For example, a first power line M1_R1 and a second power line M1_R2 may be provided below a substrate 100. The first power line M1_R1 may be a conduction path, to which a first voltage VSS (e.g., a ground voltage) is provided. The second power line M1_R2 may be a conduction path, to which a second voltage VDD (e.g., a power voltage) is provided.

The single height cell SHC may be defined between the first power line M1_R1 and the second power line M1_R2. The single height cell SHC may include one p-type MOSFET (PMOSFET) region PR and one n-type MOSFET (NMOSFET) region NR. For example, the single height cell SHC may have a CMOS structure provided between the first and second power lines M1_R1 and M1_R2.

Each of the PMOS and NMOS regions PR and NR may have a first width W1 in a first direction D1. A length of the single height cell SHC in the first direction D1 may be defined as a first height HE1. The first height HE1 may be substantially equal to a distance (e.g., a pitch) between the first and second power lines M1_R1 and M1_R2.

The single height cell SHC may constitute a single logic cell. In the present specification, the logic cell may refer to a logic device (e.g., AND, OR, XOR, XNOR, inverter, and so forth), which is configured to execute a corresponding logic function or operation, or a cell in which the logic device is implemented. For example, the logic cell may include transistors constituting the logic device and interconnection lines electrically connecting transistors to each other or connection the transistors to other circuit elements.

Referring to FIG. 2, a double height cell DHC may be provided. For example, a first power line M1_R1, a second power line M1_R2, and a third power line M1_R3 may be provided on the substrate 100. The second power line M1_R2 may be disposed between the first power line M1_R1 and the third power line M1_R3. Each of the first and third power lines M1_R1 and M1_R3 may be a conduction path to which the first voltage VSS is provided, and the second power line M1_R2 may be a conduction path to which the second voltage VDD is provided.

The double height cell DHC may be defined between the first power line M1_R1 and the third power line M1_R3. The double height cell DHC may include a first PMOSFET region PR1, a second PMOSFET region PR2, a first NMOSFET region NR1, and a second NMOSFET region NR2.

The first NMOSFET region NR1 may be adjacent to the first power line M1_R1. The second NMOSFET region NR2 may be adjacent to the third power line M1_R3. The first and second PMOSFET regions PR1 and PR2 may be adjacent to the second power line M1_R2. When viewed in a plan view, the second power line M1_R2 may be disposed between the first and second PMOSFET regions PR1 and PR2.

A length of the double height cell DHC in the first direction D1 may be defined as a second height HE2. The second height HE2 may be about two times the first height HE1 of FIG. 1. The first and second PMOSFET regions PR1 and PR2 of the double height cell DHC may be combined to serve as a single PMOSFET region. Thus, a channel size of the PMOS transistor of the double height cell DHC may be larger than a channel size of the PMOS transistor of the single height cell SHC of FIG. 1.

For example, the channel size of the PMOS transistor of the double height cell DHC may be about two times the channel size of the PMOS transistor of the single height cell SHC. In this case, the double height cell DHC may be operated at a higher speed than the single height cell SHC. In an embodiment, the double height cell DHC shown in FIG. 2 may be defined as a multi-height cell. Although not shown, the multi-height cell may include a triple height cell whose cell height is about three times that of the single height cell SHC.

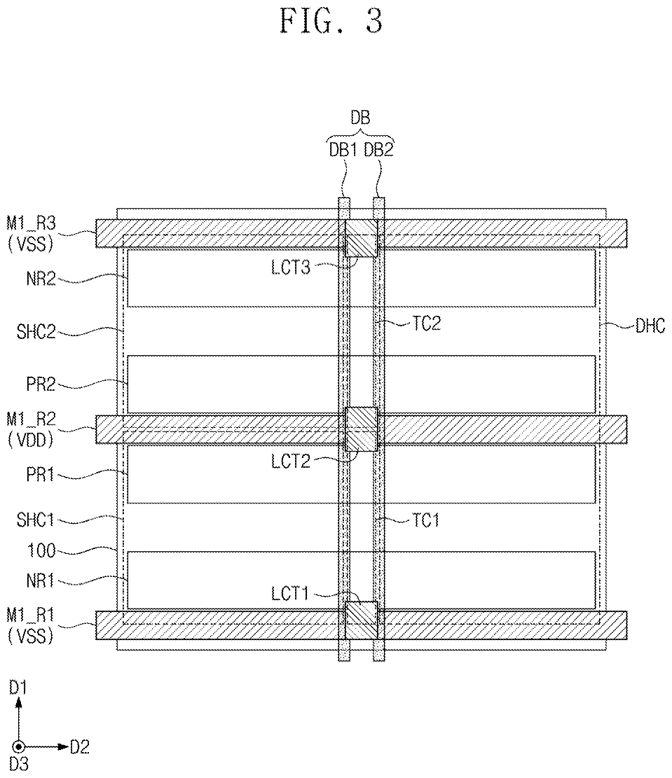

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the second and third power lines M1_R2 and M1_R3. The second single height cell SHC2 may be adjacent to the first single height cell SHC1 in the first direction D1.

The double height cell DHC may be disposed between the first and third power lines M1_R1 and M1_R3. The double height cell DHC may be adjacent to the first and second single height cells SHC1 and SHC2 in a second direction D2.

A first tab cell TC1 may be provided between the first single height cell SHC1 and the double height cell DHC. A second tab cell TC2 may be provided between the second single height cell SHC2 and the double height cell DHC. The first tab cell TC1 and the second tab cell TC2 may be aligned to each other in the first direction D1.

Each of the first and second tab cells TC1 and TC2 may be a cell, which is configured to apply a voltage from a power delivery network, which will be described later, to at least one of the power lines M1_R1 to M1_R3. The tab cell may not include a logic device, unlike a logic cell. For example, the tab cell may be configured to apply a voltage to the power line but may be just a dummy cell that does not serve as a circuit element.

As illustrated in FIG. 3, the first and second tab cells TC1 and TC2 may be disposed in a cell region with the logic cells SHC1, SHC2, and DHC to be placed between the logic cells SHC1, SHC2, and DHC. FIG. 3 illustrates an example of how the first and second tab cells TC1 and TC2 and the logic cells SHC1, SHC2, and DHC can be arranged, but there may be many other possible arrangements for the logic and tab cells.

In an embodiment, a first division structure DB1 may be provided between the first tab cell TC1 and the first single height cell SHC1 and between the second tab cell TC2 and the second single height cell SHC2. A second division structure DB2 may be provided between the first tab cell TC1 and the double height cell DHC and between the second tab cell TC2 and the double height cell DHC. An active region of the logic cell SHC1, SHC2, or DHC may be electrically disconnected from an active region of the tab cell TC1 or TC2 by the first or second division structure DB1 or DB2.

The first and second tab cells TC1 and TC2 may include first to third penetration vias LCT1, LCT2, and LCT3, which are connected to the first to third power lines M1_R1, M1_R2, and M1_R3, respectively. The first to third power lines M1_R1, M1_R2, and M1_R3 may be electrically connected to a power delivery network, which is disposed below the substrate 100, through the first to third penetration vias LCT1, LCT2, and LCT3.

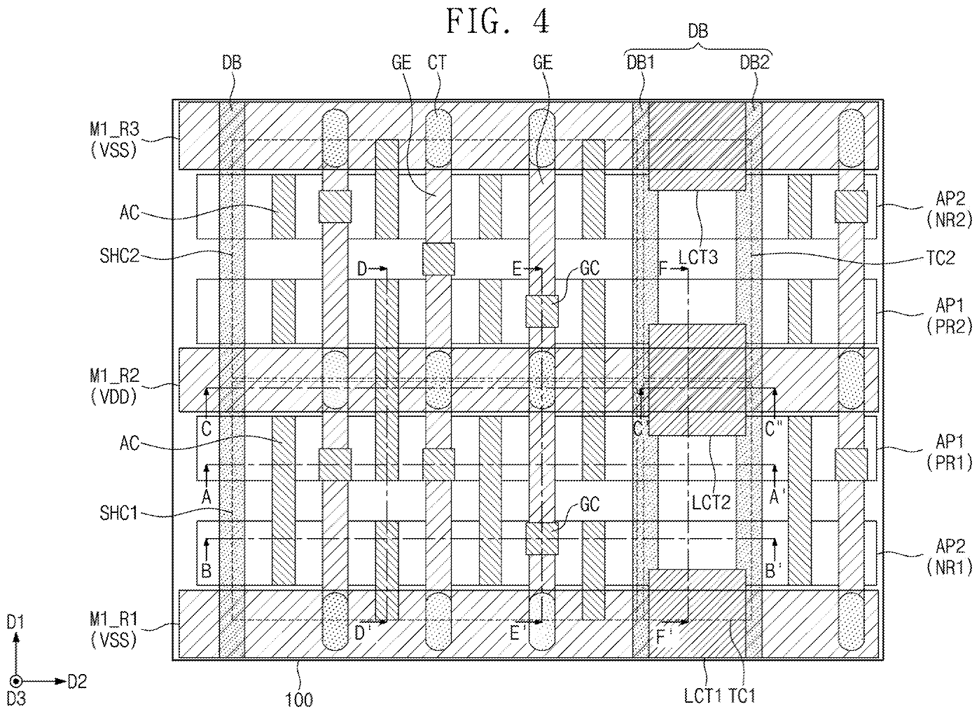

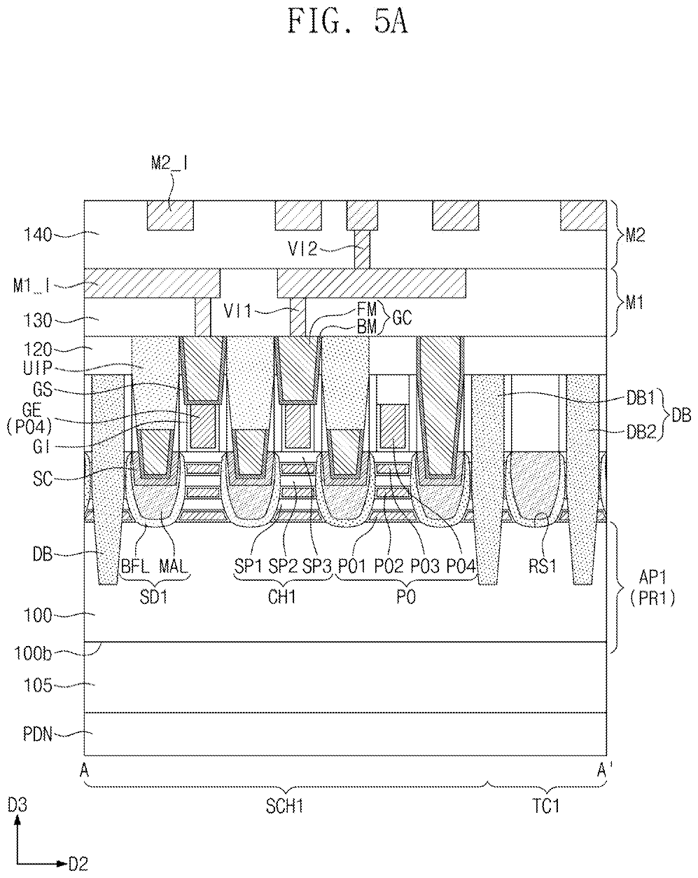

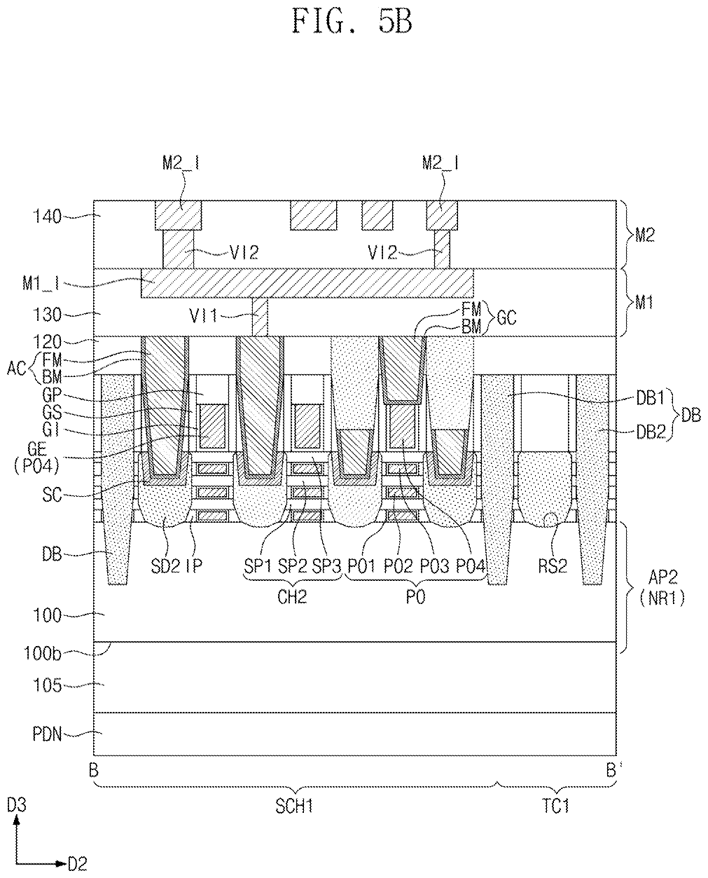

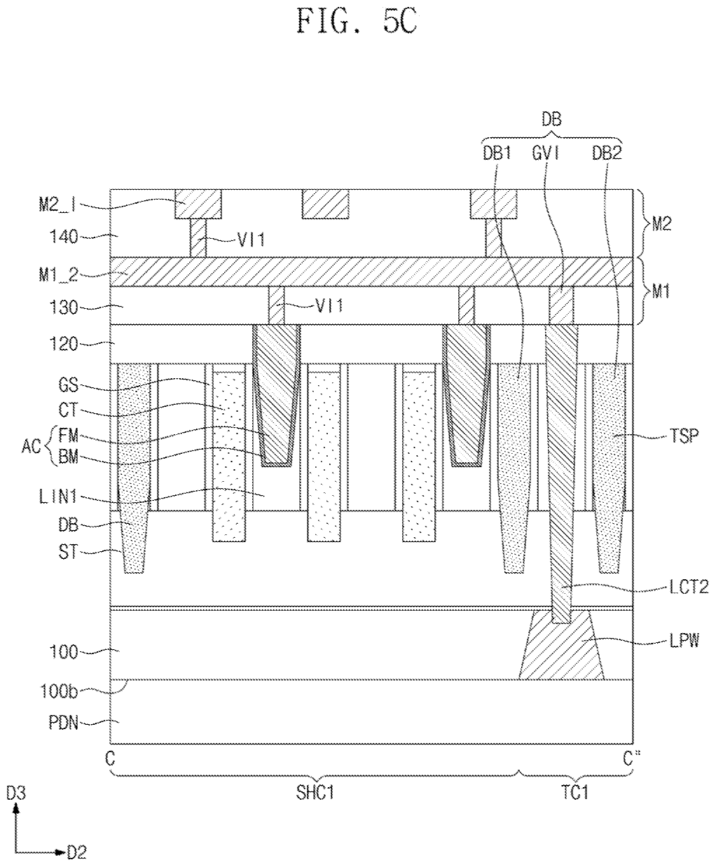

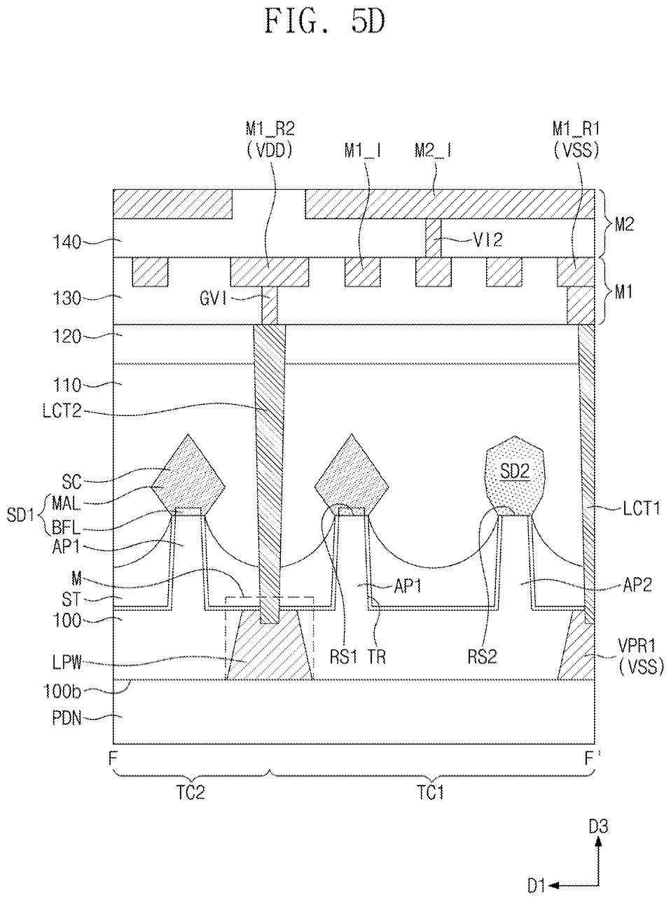

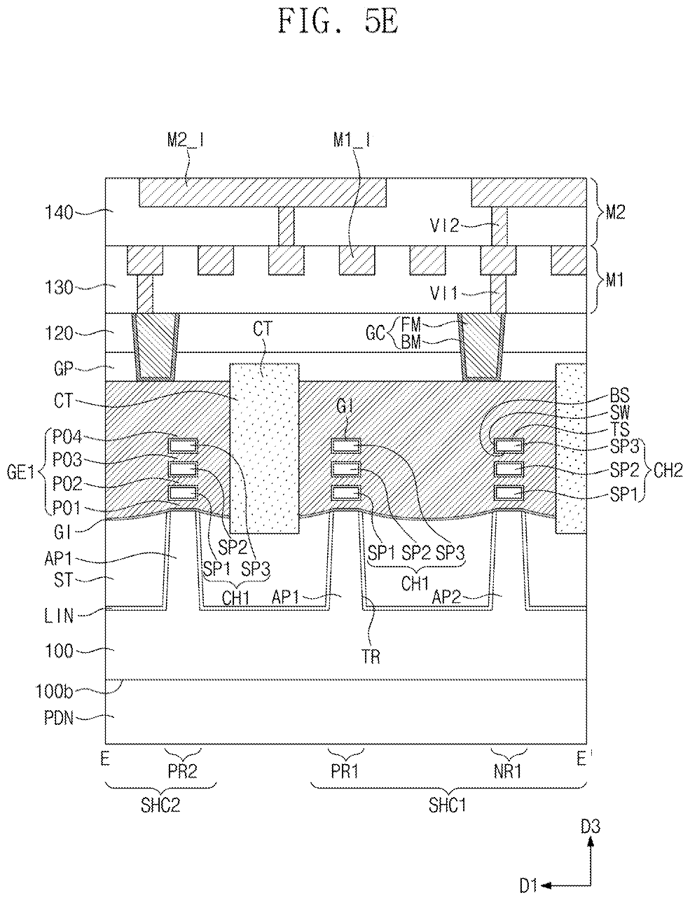

FIG. 4 is a plan view illustrating a semiconductor device according to an embodiment. FIGS. 5A to 5E are sectional views taken along lines A-A′, B-B, C-C′, D-D′, E-E′, and F-F′ of FIG. 4, respectively. FIGS. 4 and 5A to 5E illustrate a detailed example of the semiconductor device shown in FIG. 3, including the first and second single height cells SHC1 and SHC2 and the first and second tab cells TC1 and TC2.

Referring to FIG. 4 and FIGS. 5A to 5E, the first and second single height cells SHC1 and SHC2 and the first and second tab cells TC1 and TC2 may be provided on the substrate 100. Logic transistors constituting a logic circuit may be disposed on each of the first and second single height cells SHC1 and SHC2. Dummy transistors may be disposed on each of the first and second tab cells TC1 and TC2. The substrate 100 may be a semiconductor substrate that is formed of or includes silicon, germanium, silicon germanium, a compound semiconductor material, or the like. In an embodiment, the substrate 100 may be a silicon wafer.

The substrate 100 may include the first PMOSFET region PR1, the second PMOSFET region PR2, the first NMOSFET region NR1, and the second NMOSFET region NR2. Each of the first PMOSFET region PR1, the second PMOSFET region PR2, the first NMOSFET region NR1, and the second NMOSFET region NR2 may be extended in the second direction D2. The first single height cell SHC1 may include the first NMOSFET region NR1 and the first PMOSFET region PR1, and the second single height cell SHC2 may include the second PMOSFET region PR2 and the second NMOSFET region NR2.

A first active pattern AP1 and a second active pattern AP2 may be defined by a trench TR, which is formed in an upper portion of the substrate 100. The first active pattern AP1 may be provided on each of the first and second PMOSFET regions PR1 and PR2. The second active pattern AP2 may be provided on each of the first and second NMOSFET regions NR1 and NR2. The first and second active patterns AP1 and AP2 may be extended in the second direction D2. Each of the first and second active patterns AP1 and AP2 may be a vertically-protruding portion of the substrate 100.

An insulating layer LIN (FIG. 5E) may be provided on the substrate 100 and the first and second active patterns AP1 and AP2. The insulating layer LIN may be formed on a top surface of the substrate 100. A device isolation layer ST may fill the trench TR. The device isolation layer ST may be provided on the insulating layer LIN. The device isolation layer ST may be formed at a lateral side of each of the first and second active patterns AP1 and AP2. The device isolation layer ST may include a silicon oxide layer. The device isolation layer ST may not cover first and second channel patterns CH1 and CH2 to be described below. The insulating layer LIN may be formed of or include at least one of silicon oxide and silicon nitride. For example, the insulating layer LIN may be formed of or include Si₃N₄.

A first channel pattern CH1 (FIGS. 5A and 5E) may be provided on the first active pattern AP1. A second channel pattern CH2 (FIGS. 5B and 5E) may be provided on the second active pattern AP2. Each of the first and second channel patterns CH1 and CH2 may include a first semiconductor pattern SP1, a second semiconductor pattern SP2, and a third semiconductor pattern SP3, which are sequentially stacked. The first to third semiconductor patterns SP1, SP2, and SP3 may be spaced apart from each other in a vertical direction (e.g., a third direction D3).

Each of the first to third semiconductor patterns SP1, SP2, and SP3 may be formed of or include at least one of silicon (Si), germanium (Ge), and silicon germanium (SiGe). For example, each of the first to third semiconductor patterns SP1, SP2, and SP3 may be formed of or include crystalline silicon. In an embodiment, each of the first to third semiconductor patterns SP1, SP2, and SP3 may be a nanosheet.

A plurality of first source/drain patterns SD1 (FIG. 5A) may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., p-type). The first channel pattern CH1 may be interposed between each pair of the first source/drain patterns SD1. For example, each pair of the first source/drain patterns SD1 may be connected to each other by the stacked first to third semiconductor patterns SP1, SP2, and SP3.

A plurality of second source/drain patterns SD2 (FIG. 5B) may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., n-type). The second channel pattern CH2 may be interposed between a pair of the second source/drain patterns SD2. For example, each pair of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. As an example, a top surface of each of the first and second source/drain patterns SD1 and SD2 may be positioned at substantially the same level as a top surface of the third semiconductor pattern SP3. However, in an embodiment, the top surface of each of the first and second source/drain patterns SD1 and SD2 may be higher than the top surface of the third semiconductor pattern SP3.

The first source/drain patterns SD1 may include a semiconductor material (e.g., SiGe) whose lattice constant is greater than that of the substrate 100. In this case, the pair of the first source/drain patterns SD1 may exert a compressive stress on the first channel patterns CH1 therebetween. The second source/drain patterns SD2 may be formed of or include the same semiconductor element (e.g., Si) as the substrate 100.

Each of the first source/drain patterns SD1 may include a buffer layer BFL and a main layer MAL on the buffer layer BFL. Referring back to FIG. 5A, the buffer layer BFL may be formed on an inner surface the first recess RS1. The buffer layer BFL may have a ‘U’-shaped section corresponding to a profile of the first recess RS1.

The main layer MAL may fill an unfilled region of the first recess RS1 with the buffer layer BFL thereon. The main layer MAL may have a volume that is greater than that of the buffer layer BFL. Each of the buffer and main layers BFL and MAL may be formed of or include silicon germanium (SiGe). For example, the buffer layer BFL may contain a relatively low concentration of germanium (Ge). In another embodiment, the buffer layer BFL may contain only silicon (Si), without germanium (Ge). A germanium concentration of the buffer layer BFL may range from 0 at % to 30 at %.

The main layer MAL may contain a relatively high concentration of germanium. In an embodiment, the germanium concentration of the main layer MAL may range from 30 at % to 70 at %. The germanium concentration of the main layer MAL may increase in the third direction D3. For example, a portion of the main layer MAL, which is adjacent to the buffer layer BFL, may have a germanium concentration of about 40 at %, and an upper portion of the main layer MAL may have a germanium concentration of about 60 at %.

Each of the buffer and main layers BFL and MAL may contain an impurity (e.g., boron, gallium, or indium) that allows the first source/drain pattern SD1 to have a p-type conductivity. The impurity concentration of each of the buffer and main layers BFL and MAL may range from 1E18 atoms/cm³ to 5E22 atoms/cm³. The impurity concentration of the main layer MAL may be higher than the impurity concentration of the buffer layer BFL.

The buffer layer BFL may prevent a stacking fault between the substrate 100 (i.e., the first active pattern AP1) and the main layer MAL and between each of the first to third semiconductor patterns SP1, SP2, and SP3 and the main layer MAL. The stacking fault may lead to an increase of a channel resistance. The buffer layer BFL may be used to protect the main layer MAL in a process of replacing second semiconductor layers SAL with first to third inner electrodes PO1, PO2, and PO3 of a gate electrode GE, as will be described later. For example, the buffer layer BFL may prevent an etchant material, which is used to remove the second semiconductor layers SAL, from entering and etching the main layer MAL.

Each of the second source/drain patterns SD2 may be formed of or include silicon (Si). The second source/drain pattern SD2 may further contain impurities (e.g., phosphorus, arsenic, or antimony) that allow the second source/drain pattern SD2 to have an n-type conductivity. The impurity concentration of the second source/drain pattern SD2 may range from 1E18 atom/cm³ to 5E22 atom/cm³.

The gate electrodes GE may be provided to cross the first and second channel patterns CH1 and CH2 and to extend in the first direction D1. The gate electrodes GE may be arranged at a first pitch in the second direction D2. Each of the gate electrodes GE may vertically overlap the first and second channel patterns CH1 and CH2.

The gate electrode GE may include a first inner electrode PO1 interposed between each of the active pattern AP1 and AP2 and the first semiconductor pattern SP1, a second inner electrode PO2 interposed between the first semiconductor pattern SP1 and the second semiconductor pattern SP2, a third inner electrode PO3 interposed between the second semiconductor pattern SP2 and the third semiconductor pattern SP3, and an outer electrode PO4 on the third semiconductor pattern SP3.

Referring back to FIG. 5E, the gate electrode GE may be provided on a top surface TS, a bottom surface BS, and opposite side surfaces SW of each of the first to third semiconductor patterns SP1, SP2, and SP3. For example, the transistor according to the present embodiment may be a three-dimensional field effect transistor, for example, multi-bridge channel field-effect transistor (MBCFET) or a gate-all-around field-effect transistor (GAAFET) in which the gate electrode GE is provided to three-dimensionally surround the channel pattern. The embodiments herein may also apply to a fin field-effect transistor (FinFET) in which one or more vertically protruding fin structures from a channel pattern.

Gate cutting patterns CT (FIG. 5C) may be provided on a boundary region between the first and second single height cells SHC1 and SHC2. The gate cutting patterns CT may be arranged along the boundary. When viewed in a plan view, the gate cutting patterns CT may be disposed to overlap the gate electrodes GE, respectively. The gate cutting patterns CT may be formed of or include at least one of insulating materials such as silicon oxide, silicon nitride, or combinations thereof, not being limited thereto.

The gate electrode GE on the first single height cell SHC1 may be separated from the gate electrode GE on the second single height cell SHC2 by the gate cutting pattern CT. The gate cutting pattern CT may be interposed between the gate electrodes GE, which are placed on the first and second single height cells SHC1 and SHC2 aligned to each other in the first direction D1. For example, the gate electrode GE extending in the first direction D1 may be divided into a plurality of the gate electrodes GE by the gate cutting patterns CT.

Referring to FIGS. 5A to 5C, a pair of gate spacers GS may be respectively disposed on opposite side surfaces of the outer electrode PO4 of the gate electrode GE. The gate spacers GS may be extended along the gate electrode GE and in the first direction D1. Top surfaces of the gate spacers GS may be higher than a top surface of the gate electrode GE. The top surfaces of the gate spacers GS may be coplanar with a top surface of a first interlayer insulating layer 110, which will be described later. The gate spacers GS may be formed of or include at least one of SiCN, SiCON, and SiN. In an embodiment, the gate spacers GS may be a multi-layered structure, which includes at least two different materials selected from SiCN, SiCON, and SiN.

A gate capping pattern GP may be provided on the gate electrode GE. The gate capping pattern GP may be extended along the gate electrode GE or in the first direction D1. The gate capping pattern GP may be formed of or include a material having an etch selectivity with respect to the first interlayer insulating layer 110 and a second interlayer insulating layer 120, which will be described later. For example, the gate capping pattern GP may be formed of or include at least one of SiON, SiCN, SiCON, and SiN.

A gate insulating layer GI may be interposed between the gate electrode GE and the first channel pattern CH1 and between the gate electrode GE and the second channel pattern CH2. The gate insulating layer GI may cover the top surface TS, the bottom surface BS, and opposite side surfaces SW1 and SW2 of each of the first to third semiconductor patterns SP1, SP2, and SP3. The gate insulating layer GI may be formed on a top surface of the device isolation layer ST below the gate electrode GE.

In an embodiment, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate.

The gate electrode GE may include a first electrode pattern and a second electrode pattern on the first electrode pattern. The first electrode pattern may be provided on the gate insulating layer GI and may be adjacent to the first to third semiconductor patterns SP1, SP2, and SP3. The first electrode pattern may include a work-function metal, which can be used to adjust a threshold voltage of the transistor. By adjusting a thickness and composition of the first electrode pattern, it may be possible to realize a transistor having a desired threshold voltage. For example, the first to third inner electrodes PO1, PO2, and PO3 of the gate electrode GE may be composed of the first electrode pattern including the work-function metal.

The first electrode pattern may include a metal nitride layer. For example, the first electrode pattern may include nitrogen (N) and at least one metal selected from titanium (Ti), tantalum (Ta), aluminum (Al), tungsten (W), and molybdenum (Mo). In an embodiment, the first electrode pattern may further include carbon (C). The first electrode pattern may include a plurality of work function metal layers which are stacked.

The second electrode pattern may be formed of or include a metallic material whose resistance is lower than the first electrode pattern. For example, the second electrode pattern may be formed of or include at least one metallic material, which is selected from the group consisting of tungsten (W), aluminum (Al), cobalt (Co), titanium (Ti), and tantalum (Ta). In an embodiment, the outer electrode PO4 of the gate electrode GE may include the first electrode pattern and the second electrode pattern on the first electrode pattern.

Referring back to FIG. 5B, inner spacers IP may be provided on the first and second NMOSFET regions NR1 and NR2. For example, the inner spacers IP may be provided above the second active pattern AP2. The inner spacers IP may be respectively interposed between the second source/drain pattern SD2 and the first to third inner electrodes PO1, PO2, and PO3 of the gate electrode GE. The inner spacers IP may be in direct contact with the second source/drain pattern SD2. Each of the first to third inner electrodes PO1, PO2, and PO3 of the gate electrode GE may be spaced apart from the second source/drain pattern SD2 by the inner spacer IP.

The first interlayer insulating layer 110 may be provided on the substrate 100. The first interlayer insulating layer 110 may be formed on the gate spacers GS and the first and second source/drain patterns SD1 and SD2. The first interlayer insulating layer 110 may have a top surface that is substantially coplanar with a top surface of the gate capping pattern GP and the top surface of the gate spacer GS. A second interlayer insulating layer 120 may be formed on the first interlayer insulating layer 110 and on the gate capping pattern GP. A third interlayer insulating layer 130 may be provided on the second interlayer insulating layer 120. A fourth interlayer insulating layer 140 may be provided on the third interlayer insulating layer 130. In an embodiment, at least one of the first to fourth interlayer insulating layers 110 to 140 may include a silicon oxide layer.

The division structures DB may be respectively provided on boundaries between the cells. For example, the first division structure DB1 may be provided between the first and second single height cells SHC1 and SHC2 and the first and second tab cells TC1 and TC2. The second division structure DB2 may be provided between the first and second tab cells TC1 and TC2 and other logic cells adjacent thereto. Each of the first and second tab cells TC1 and TC2 may be provided between a pair of the division structures DB1 and DB2.

The division structure DB may be extended in the first direction D1 to be parallel to the gate electrodes GE. A distance between the division structure DB and the gate electrode GE, which are adjacent to each other, may be equal to the first pitch between two adjacent gate electrodes in the second direction D2. In an embodiment, a width of each of the first and second tab cells TC1 and TC2 in the second direction D2 may be substantially equal to the first pitch.

Referring to FIGS. 5A to 5C, the division structure DB may be provided to penetrate the gate capping pattern GP and the gate electrode GE and may be extended into the first and second active patterns AP1 and AP2. The division structure DB may be provided to penetrate an upper portion of each of the first and second active patterns AP1 and AP2. The division structure DB may electrically separate an active region of one cell from an active region of an adjacent cell.

Referring to FIGS. 4 and 5A to 5D, active contacts AC may be provided to penetrate the first and second interlayer insulating layers 110 and 120 and to be electrically connected to the first and second source/drain patterns SD1 and SD2, respectively. A pair of the active contacts AC may be respectively provided at both sides of the gate electrode GE. When viewed in a plan view; the active contact AC may be a bar-shaped pattern that is extended in the first direction D1.

The active contact AC may be a self-aligned contact. For example, the active contact AC may be formed by a self-alignment process using the gate capping pattern GP and the gate spacer GS. For example, the active contact AC may be formed on at least a portion of the side surface of the gate spacer GS. Although not shown, the active contact AC may be provided on a portion of the top surface of the gate capping pattern GP.

Metal-semiconductor compound layers SC (e.g., silicide layers) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, and cobalt silicide.

Referring to FIGS. 4 and 5A to 5E, gate contacts GC may be provided to penetrate the second interlayer insulating layer 120 and the gate capping pattern GP to be electrically connected to the gate electrodes GE, respectively. When viewed in a plan view, two gate contacts GC on the first single height cell SHC1 may be disposed to overlap the first PMOSFET region PR1. For example, the two gate contacts GC on the first single height cell SHC1 may be provided vertically above the first active pattern AP1 (e.g., see FIG. 5A). When viewed in a plan view, one gate contact GC on the first single height cell SHC1 may be disposed to overlap the first NMOSFET region NR1. For example, the one gate contact GC on the first single height cell SHC1 may be provided vertically above the second active pattern AP2 (e.g., see FIG. 5B).

The gate contact GC may be freely disposed on the gate electrode GE, without any restrictions on its position. For example, the gate contacts GC on the second single height cell SHC2 may be respectively disposed vertically above the second PMOSFET region PR2, the second NMOSFET region NR2, and the device isolation layer ST filling the trench TR (e.g., see FIG. 4).

In an embodiment, referring to FIGS. 5A and 5B, an upper insulating pattern UIP may be formed vertically above at least a portion of the active contact AC adjacent to the gate contact GC. A bottom surface of the upper insulating pattern UIP may be lower than a bottom surface of the gate contact GC. For example, a top surface of the active contact AC adjacent to the gate contact GC may be formed at a level, which is lower than the bottom surface of the gate contact GC, due to the upper insulating pattern UIP. Accordingly, it may be possible to prevent the gate contact GC and the active contact AC, which are adjacent to each other, from being in contact with each other and thereby to prevent a short circuit issue from occurring therebetween.

Each of the active contacts AC and the gate contacts GC may include a conductive pattern FM and a barrier pattern BM enclosing the conductive pattern FM. For example, the conductive pattern FM may be formed of or include at least one of metallic materials (e.g., aluminum, copper, tungsten, molybdenum, and cobalt). The barrier pattern BM may be provided to cover side and bottom surfaces of the conductive pattern FM. In an embodiment, the barrier pattern BM may include a metal layer and a metal nitride layer. The metal layer may be formed of or include at least one of titanium, tantalum, tungsten, nickel, cobalt, and platinum. The metal nitride layer may be formed of or include at least one of titanium nitride (TiN), tantalum nitride (TaN), tungsten nitride (WN), nickel nitride (NiN), cobalt nitride (CoN), and platinum nitride (PtN).

Referring to FIGS. 4 and 5A to 5E, a first metal layer M1 may be provided in the third interlayer insulating layer 130. The first metal layer M1 may include the first to third power lines M1_R1, M1_R2, and M1_R3.

The first to third power lines M1_R1, M1_R2, and M1_R3 may be extended in the second direction D2 to be parallel to each other. The first power line M1_R1 may be placed on a border of the first single height cell SHC1. The second power line M1_R2 may be placed on a boundary between the first and second single height cells SHC1 and SHC2. The third power line M1_R3 may be placed on a border of the second single height cell SHC2.

Referring back to FIGS. 5C and 5E, the second power line M1_R2 may be electrically connected to at least one active contact AC. A first via VI1 may be provided between the second power line M1_R2 and the at least one active contact AC.

Referring to FIGS. 4, 5C, and 5E, first to third lower contacts LCT1, LCT2, and LCT3 may be provided in the first and second tab cells TC1 and TC2. The first to third lower contacts LCT1, LCT2, and LCT3 may be electrically connected to the first to third power lines M1_R1, M1_R2, and M1_R3, respectively.

For example, the second lower contact LCT2 may be vertically extended, at a lateral side of the first source/drain pattern SD1 or the second source/drain pattern SD2, from the second interlayer insulating layer 120 to an inside or a bottom surface 100b of the substrate 100. A top surface of the second lower contact LCT2 may be coplanar with a top surface of the second interlayer insulating layer 120. In an embodiment, a bottom surface of the second lower contact LCT2 may be lower than the top surface of the substrate 100. The bottom surface of the second lower contact LCT2 may also be at level lower than a bottom surface of the first and second source/drain patterns SD1 and SD2 and/or a level lower than a bottom surface of the device isolation layer ST and a bottom portion of the active patterns AP1 and AP2. A giant via GVI may be provided between the second lower contact LCT2 and the second power line M1_R2. The second lower contact LCT2 and the second power line M1_R2 may be electrically connected to each other through the giant via GVI.

A lower power structure LPW may be provided in the substrate 100. The lower power structure LPW may be provided at a level below the device isolation layer ST. The lower power structure LPW may be connected to at least one of the lower contacts LCT1, LCT2 and LCT3. A lower power structure LPW may vertically overlap at least one of the lower contacts LCT1, LCT2 and LCT3. The lower contacts LCT1, LCT2, LCT3 and the lower power structure LPW may be formed of or include at least one of tungsten (W), cobalt (Co), and molybdenum (Mo). The lower contacts LCT1, LCT2 and LCT3 may be formed of or include a material that is the same as or different from the lower power structure LPW.

A power delivery network layer PDN may be provided under the substrate 100. The power delivery network layer PDN may include a plurality of lower interconnection lines, which are electrically connected to the lower power structure LPW. For example, the power delivery network layer PDN may be electrically connected to the first to third power lines M1_R1, M1_R2, and M1_R3.

In an embodiment, the power delivery network layer PDN may include an interconnection network, which is used to apply the first voltage VSS to the first and third power lines M1_R1 and M1_R3. The power delivery network layer PDN may include an interconnection network, which is used to apply the second voltage VDD to the second power line M1_R2.

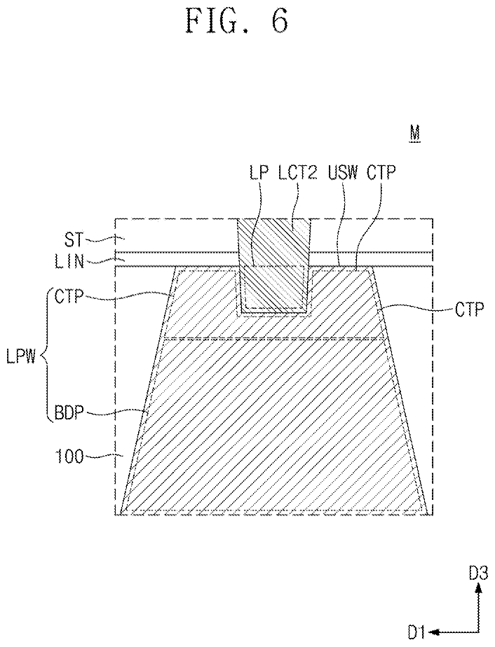

FIG. 6 is an enlarged sectional view illustrating a portion ‘M’ of FIG. 5D. The lower power structure LPW and the lower contact LCT2 will be described in more detail with reference to FIG. 6.

According to an embodiment, the lower power structure LPW may include a body portion BDP and a connecting portion CTP on the body portion BDP. The connecting portion CTP may be a portion of the lower power structure LPW connected to the lower contact LCT2. The connecting portion CTP may be a dome- or crater-shaped portion enclosing the lower contact LCT2. The lower contact LCT2 may include a protruding portion LP buried in the connecting portion CTP. The connecting portion CTP may be provided to enclose a bottom surface and opposite side surfaces of the protruding portion LP. A top surface USW of the connecting portion CTP may be higher than the bottom surface of the protruding portion LP.

The insulating layer LIN may be interposed between the connecting portion CTP and the device isolation layer ST. The top surface USW of the connecting portion CTP may be in direct contact with the insulating layer LIN. At least a portion of the side surfaces of the lower contact LCT2 may be in contact with the insulating layer LIN. For example, the lower contact LCT2 may penetrate the device isolation layer ST and the insulating layer LIN and may be inserted into the lower power structure LPW. The insulating layer LIN may be formed of or include at least one of silicon oxide and silicon nitride.

As a height in the third direction D3 increases, a width of the lower contact LCT may increase. In other words, as a distance to the power delivery network layer PDN decreases, the width of the lower contact LCT may decrease. As a distance to the power delivery network layer PDN decreases, a width of the lower power structure LPW increase.

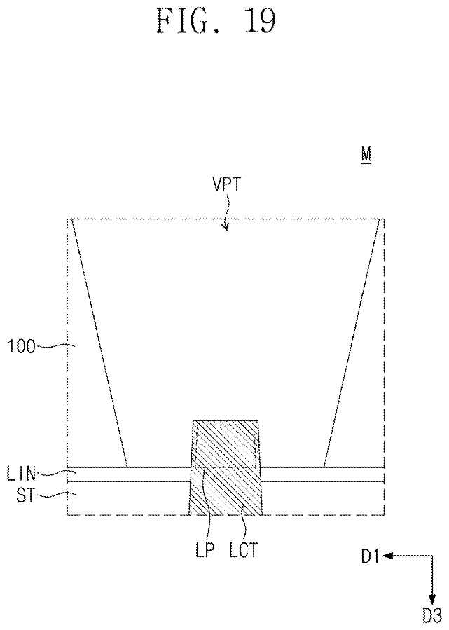

The insulating layer LIN may be interposed between the lower power structure LPW and the device isolation layer ST. Thus, it may be possible to prevent the device isolation layer ST from being removed in a subsequent step of removing a protective capping pattern CAP, as will be described with reference to FIG. 19. The protective capping pattern CAP may prevent the lower contact LCT from being damaged in subsequent manufacturing steps. As a result, it may be possible to increase the yield in the semiconductor manufacturing process and improve the electrical and reliability characteristics of the semiconductor device.

Referring to FIG. 4 and FIGS. 5A to 5E, the first metal layer M1 may further include first interconnection lines M1_I. The first interconnection lines M1_I may be extended in the second direction D2 to be parallel to each other.

The first metal layer M1 may further include the first vias VI1. The first vias VI1 may be respectively provided below the first interconnection lines M1_I of the first metal layer M1. The active contact AC and the first interconnection line M1_I may be electrically connected to each other through the first via VI1. The gate contact GC and the first interconnection line M1_I may be electrically connected to each other through the first via VI1.

The first interconnection line M1_I of the first metal layer M1 and the first via VI1 thereunder may be separately formed by different processes. That is, each of the first interconnection line M1_I and the first via VI1 of the first metal layer M1 may be formed by a single damascene process. The semiconductor device according to the present embodiment may be manufactured using a sub-20 nm process.

A second metal layer M2 may be provided in a fourth interlayer insulating layer 140. The second metal layer M2 may include a plurality of second interconnection lines M2_I. Each of the second interconnection lines M2_I of the second metal layer M2 may be a line- or bar-shaped pattern that is extended in the first direction D1. In other words, the second interconnection lines M2_I may be extended in the first direction D1 to be parallel to each other.

The second metal layer M2 may further include second vias VI2, which are respectively provided below the second interconnection lines M2_I. The first interconnection line M1_I of the first metal layer M1 and the second interconnection line M2_I of the second metal layer M2 may be electrically connected to each other through the second via VI2. As an example, the second interconnection line M2_I of the second metal layer M2 and the second via VI2 thereunder may be formed by a dual damascene process.

The first interconnection line M1_I of the first metal layer M1 and the second interconnection line M2_I of the second metal layer M2 may be formed of or include the same conductive material or different conductive materials. For example, the first interconnection line M1_I of the first metal layer M1 and the second interconnection line M2_I of the second metal layer M2 may be formed of or include at least one of metallic materials (e.g., aluminum, copper, tungsten, molybdenum, ruthenium, and cobalt). Although not shown, a plurality of metal layers (e.g., M3, M4, M5, and so forth) may be additionally stacked on the fourth interlayer insulating layer 140. Each of the stacked metal layers may include interconnection lines, which are used as routing paths between cells.

In an embodiment, the lower contact LCT2 and the lower power structure LPW may be separately formed through at least two different processes. For example, vertical contacts, which are extended from the power delivery network layer PDN to the first metal layer M1, may include two separate structures (e.g., the lower contact LCT2 and the lower power structure LPW), which are independently formed.

The lower contact LCT2 and the lower power structure LPW may be separately formed above and below the top surface, respectively, of the substrate 100. For example, the lower contact LCT2 may extend from the first metal layer M1 down to below the front surface of the substrate 100, and the lower power structure LPW may be formed below the front surface of the substrate 100. Thus, it may be possible to reduce a chip area for the vertical contacts. Hence, a size of a tab cell may be reduced, as will be described below.

According to an embodiment, the tab cell TC1 or TC2 may be provided to have a size corresponding to the first pitch, which is a distance between two adjacent gate electrodes GE in the second direction D2. That is, according to an embodiment, the tab cell TC1 or TC2 may have a very small size. As the size of the tab cell TC1 or TC2 decreases, an area of logic cells, which are disposed in a logic die, may increase. As a result, it may be possible to increase an integration density of the semiconductor device.

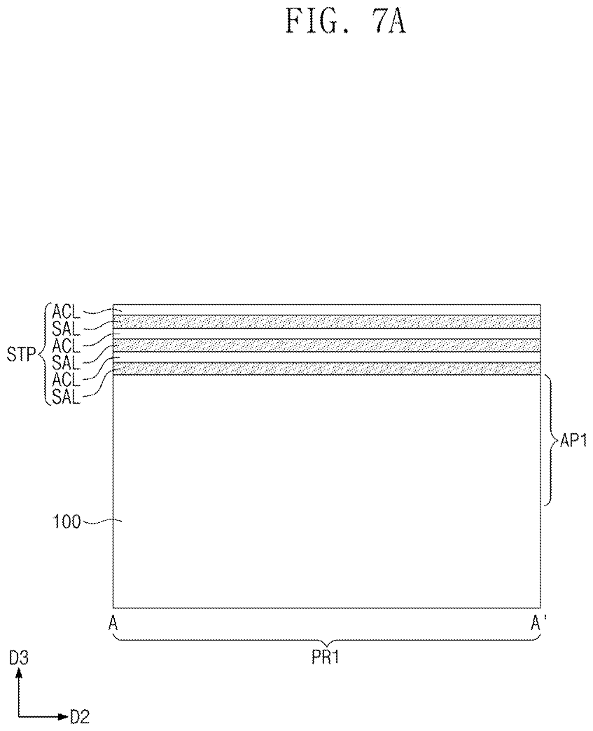

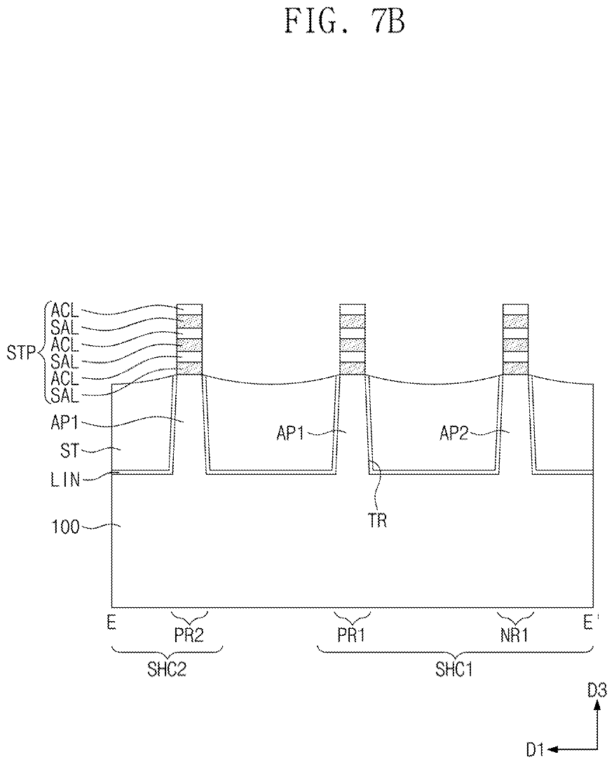

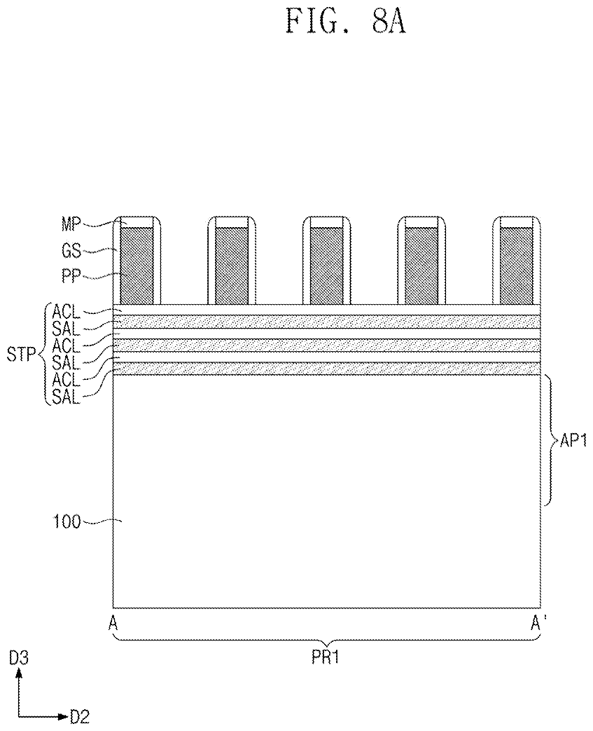

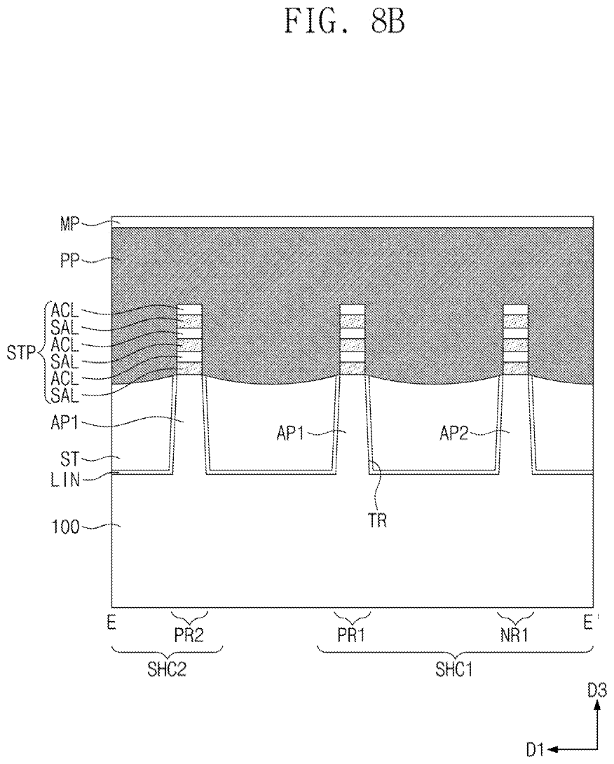

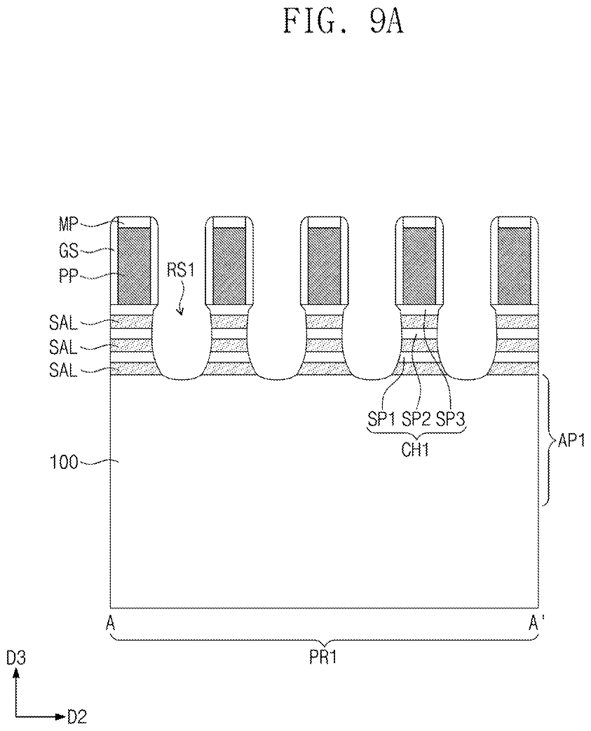

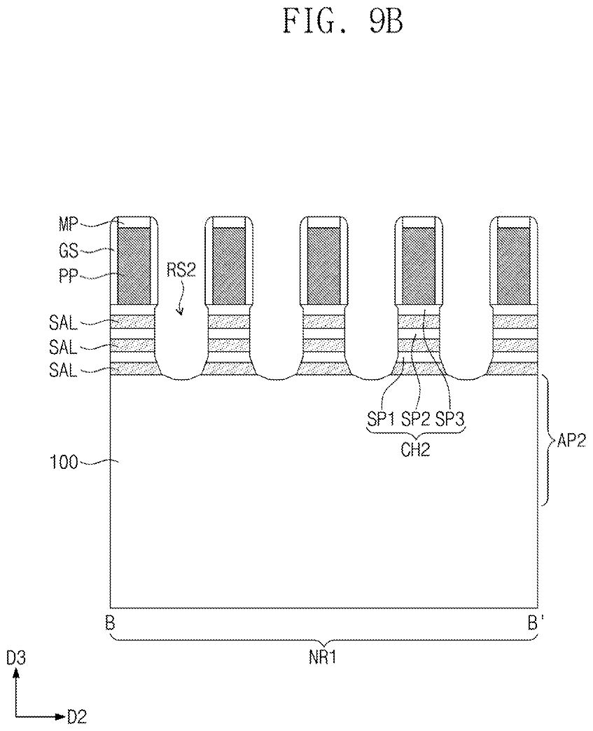

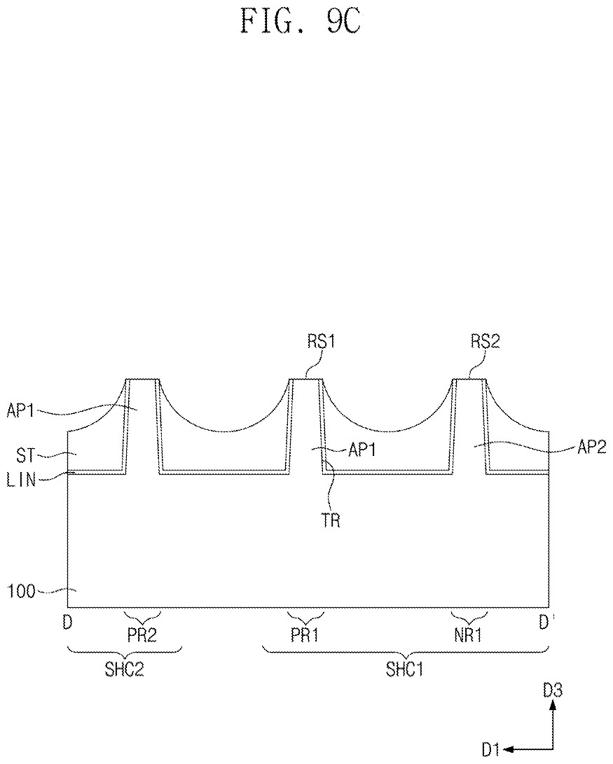

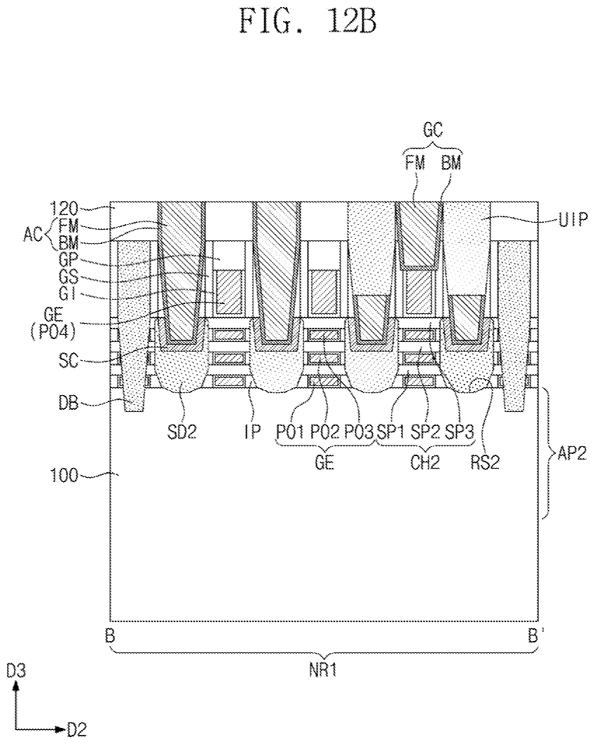

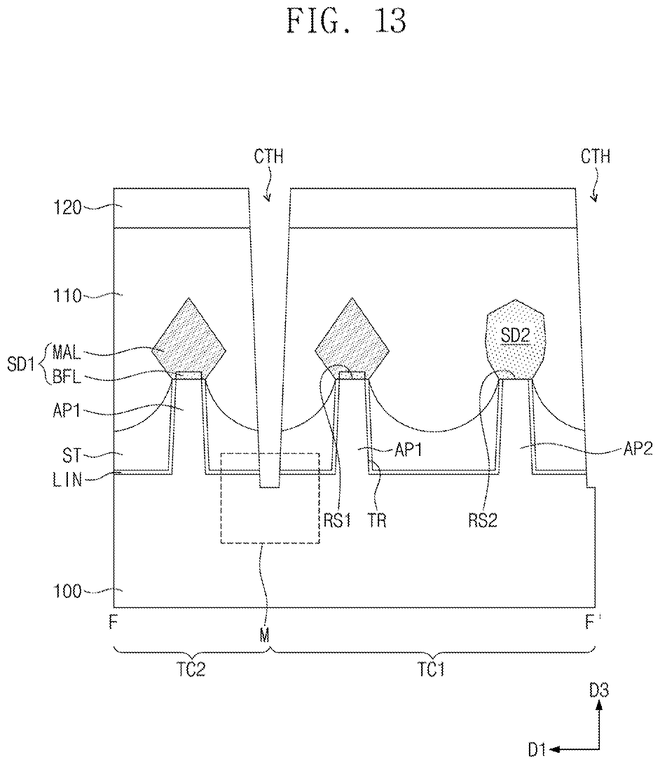

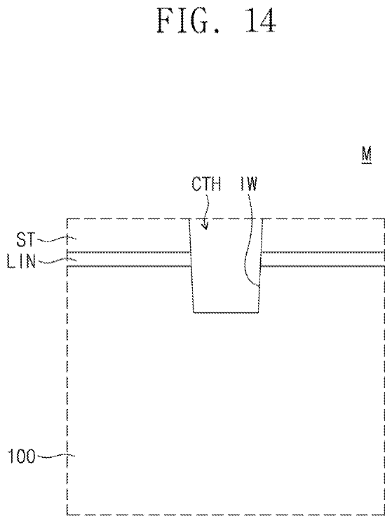

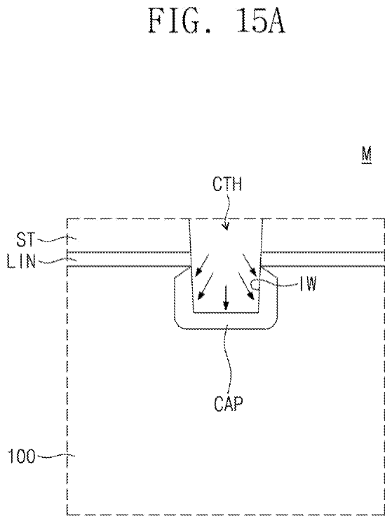

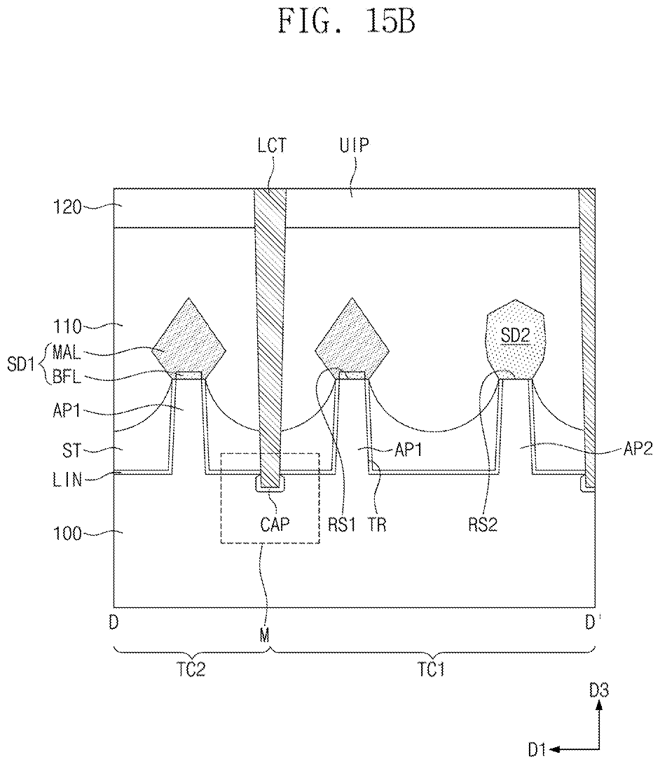

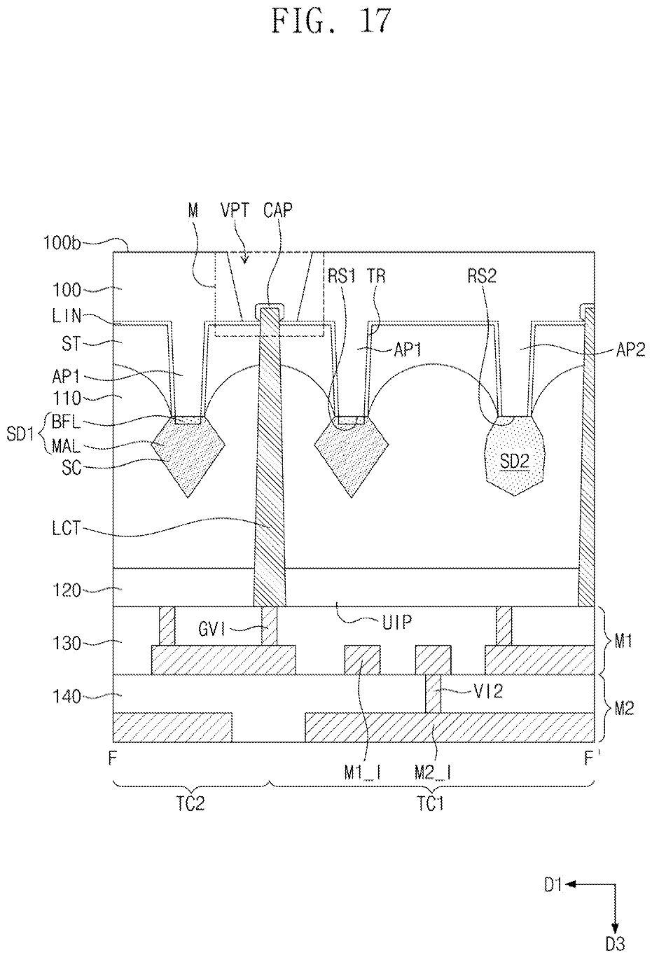

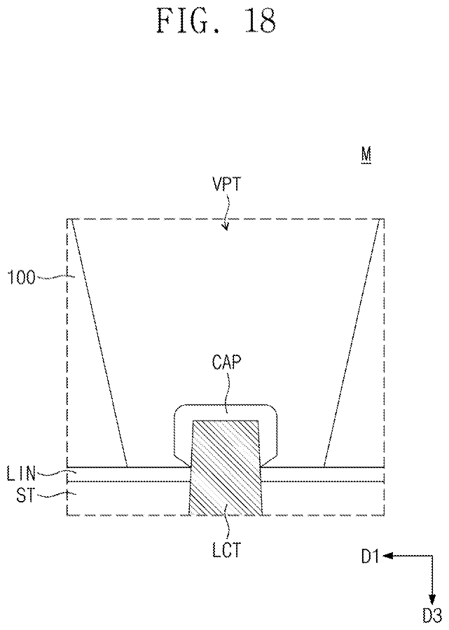

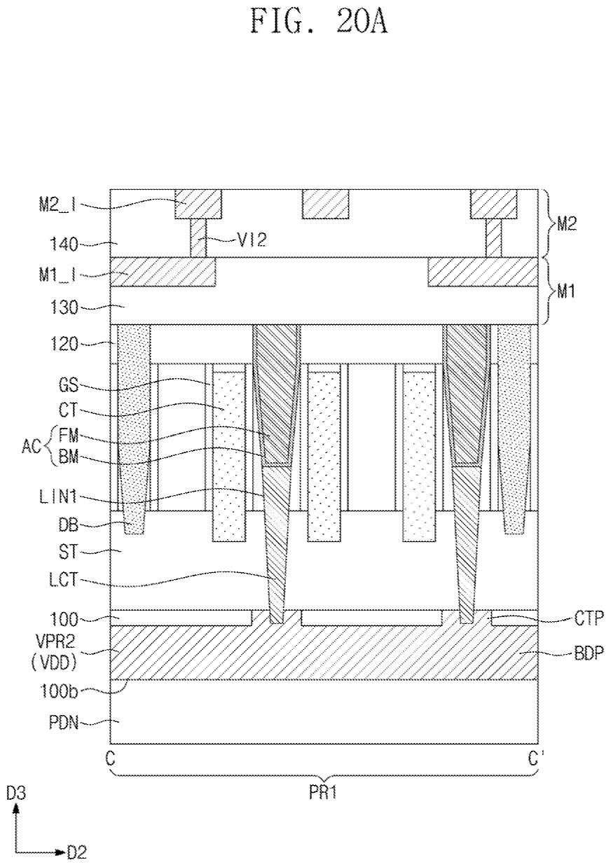

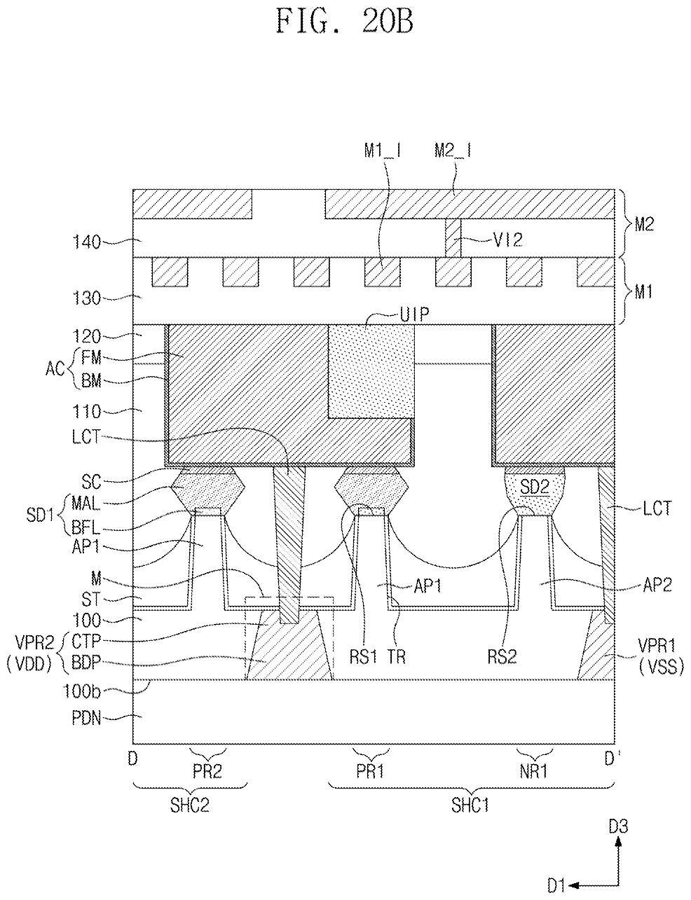

FIGS. 7A and 7B to 19 are sectional views illustrating a method of manufacturing a semiconductor device according to an embodiment. FIGS. 7A, 8A, 9A, 10A, 11A, and 12A are sectional views corresponding to the line A-A′ of FIG. 4. FIGS. 9B, 10B, 11B, and 12B are sectional views corresponding to the line B-B′ of FIG. 4. FIG. 20A is a sectional view corresponding to the line C-C′ of FIG. 4. FIGS. 9C, 10C, 11C, 15B and 20B are sectional views corresponding to the line D-D′ of FIG. 4. FIGS. 7B and 8B are sectional views corresponding to the line E-E′ of FIG. 4. FIGS. 13, 15C, 16, and 17 are sectional views corresponding to the line F-F′ of FIG. 4. FIGS. 14 and 15A are enlarged sectional views corresponding to a portion ‘M’ of FIG. 13. FIGS. 18 and 19 are enlarged sectional views corresponding to a portion ‘M’ of FIG. 17

Referring to FIGS. 7A and 7B, the substrate 100 including the first and second PMOSFET regions PR1 and PR2 and the first and second NMOSFET regions NR1 and NR2 may be provided. First and second semiconductor layers ACL and SAL, which are alternately stacked on the substrate 100, may be formed. Each of the first and second semiconductor layers ACL and SAL may be formed of or include at least one of silicon (Si), germanium (Ge), and silicon-germanium (SiGe), but the first and second semiconductor layers ACL and SAL may be formed of different materials from each other.

The second semiconductor layer SAL may be formed of or include a material that is chosen to have an etch selectivity with respect to the first semiconductor layer ACL. For example, the first semiconductor layers ACL may be formed of or include silicon (Si), and the second semiconductor layers SAL may be formed of or include silicon-germanium (SiGe). A germanium concentration of each of the second semiconductor layers SAL may range from 10 at % to 30 at %.

Mask patterns may be respectively formed on the first and second PMOSFET regions PR1 and PR2 and the first and second NMOSFET regions NR1 and NR2 of the substrate 100. The mask pattern may be a line- or bar-shaped pattern that is extended in the second direction D2.

A patterning process using the mask patterns as an etch mask may be performed to form the trench TR defining the first and second active patterns AP1 and AP2. The first active pattern AP1 may be formed on each of the first and second PMOSFET regions PR1 and PR2. The second active pattern AP2 may be formed on each of the first and second NMOSFET regions NR1 and NR2. When viewed in a plan view, the first and second active patterns AP1 and AP2 may be line-shaped patterns, which are extended in the second direction D2 to be parallel to each other.

A stacking pattern STP may be formed on each of the first and second active patterns AP1 and AP2. The stacking pattern STP may include the first semiconductor layers ACL and the second semiconductor layers SAL, which are alternately stacked. The stacking pattern STP may be formed along with the first and second active patterns AP1 and AP2, during the patterning process.

The insulating layer LIN may be formed on the substrate 100 and first and second active patterns AP1 and AP2. The insulating layer LIN may be formed on the entire top surface of the substrate 100. The insulating layer LIN may not cover the first and second semiconductor layers ACL and SAL. The insulating layer LIN may be formed of or include at least one of silicon oxide and silicon nitride. The insulating layer LIN may be used as a layer protecting the device isolation layer ST in a subsequent step.

The device isolation layer ST may be formed to fill the trench TR. The device isolation layer ST may be formed on the insulating layer LIN. For example, an insulating layer may be formed on the substrate 100, the first and second active patterns AP1 and AP2, and the stacking patterns STP. The device isolation layer ST may be formed by recessing the insulating layer until the stacking patterns STP are exposed.

The device isolation layer ST may be formed of or include at least one of insulating materials (e.g., silicon oxide). The stacking patterns STP may be placed above the device isolation layer ST and may be exposed to the outside of the device isolation layer ST. For example, the stacking patterns STP may protrude vertically above the device isolation layer ST.

Referring to FIGS. 8A and 8B, sacrificial patterns PP may be formed on the substrate 100 to cross the stacking patterns STP. Each of the sacrificial patterns PP may be a line- or bar-shaped pattern that is extended in the first direction D1. The sacrificial patterns PP may be arranged at a first pitch in the second direction D2.

For example, the formation of the sacrificial patterns PP may include forming a sacrificial layer on the substrate 100, forming hard mask patterns MP on the sacrificial layer, and patterning the sacrificial layer using the hard mask patterns MP as an etch mask. The sacrificial layer may be formed of or include polysilicon.

A pair of the gate spacers GS may be formed on opposite side surfaces of each of the sacrificial patterns PP. The formation of the gate spacers GS may include conformally forming a gate spacer layer on the substrate 100 and anisotropically etching the gate spacer layer. The gate spacer layer may be formed of or include silicon nitride, for example, at least one of SiCN, SiCON, and SiN. In an embodiment, the gate spacer layer may be a multi-layered structure including silicon nitride, for example, at least two of SiCN, SiCON, or SiN.

Referring to FIGS. 9A to 9C, the first recesses RS1 may be formed in the stacking pattern STP on the first active pattern AP1. The second recesses RS2 may be formed in the stacking pattern STP on the second active pattern AP2. During the formation of the first and second recesses RS1 and RS2, the device isolation layer ST may also be recessed at both sides of each of the first and second active patterns AP1 and AP2 (e.g., see FIG. 9C).

For example, the first recesses RS1 may be formed by etching the stacking pattern STP on the first active pattern AP1 using the hard mask patterns MP and the gate spacers GS as an etch mask. The first recess RS1 may be formed between a pair of the sacrificial patterns PP. The second recesses RS2 in the stacking pattern STP on the second active pattern AP2 may be formed by the same method as that for the first recesses RS1.

The first to third semiconductor patterns SP1, SP2, and SP3, which are sequentially stacked between adjacent ones of the first recesses RS1, may be formed from the first semiconductor layers ACL, respectively. The first to third semiconductor patterns SP1, SP2, and SP3, which are sequentially stacked between adjacent ones of the second recesses RS2, may be formed from the first semiconductor layers ACL, respectively. The first to third semiconductor patterns SP1, SP2, and SP3 between adjacent ones of the first recesses RS1 may constitute the first channel pattern CH1. The first to third semiconductor patterns SP1, SP2, and SP3 between the adjacent ones of the second recesses RS2 may constitute the second channel pattern CH2.

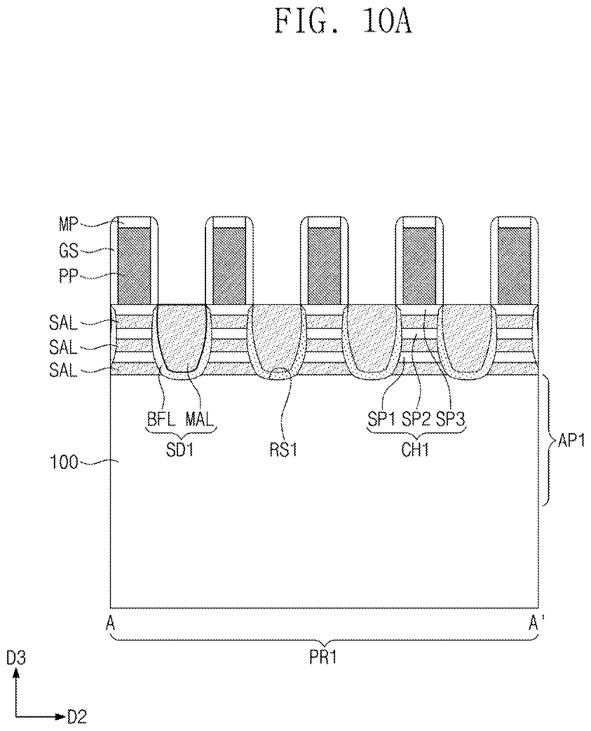

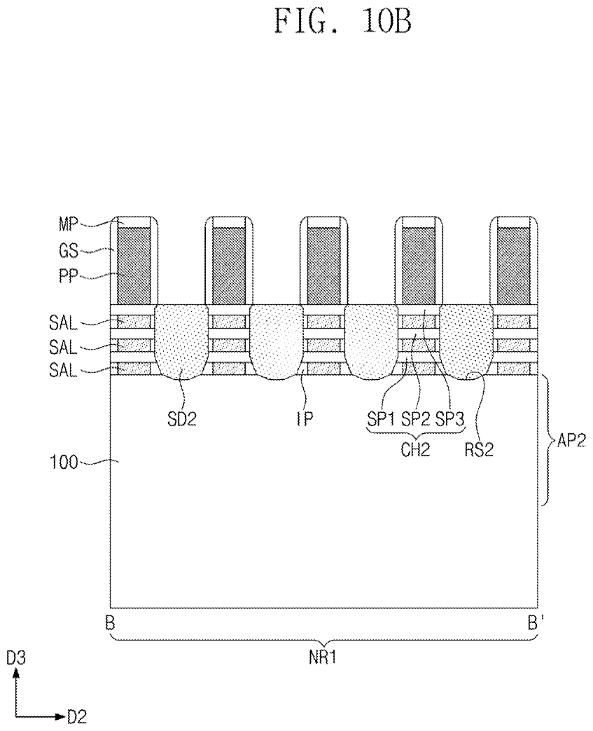

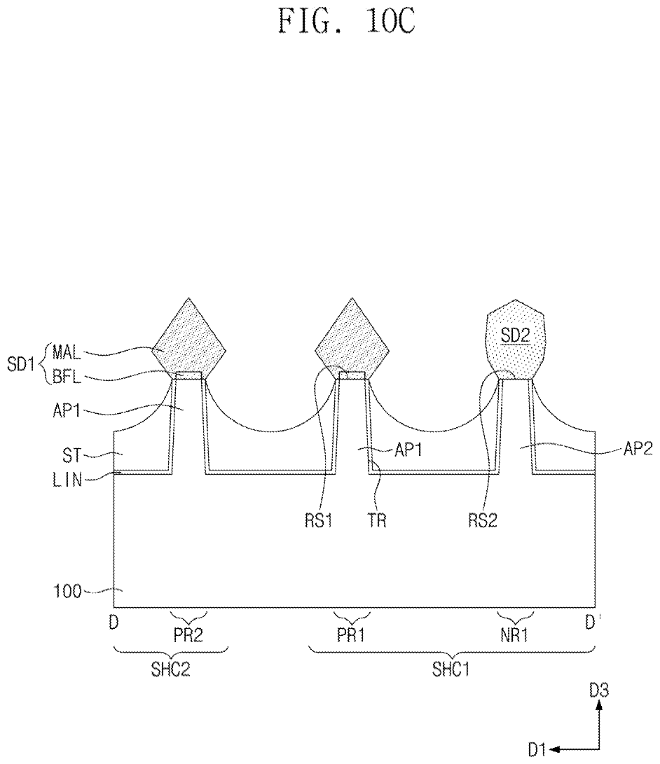

Referring to FIGS. 10A to 10C, the first source/drain patterns SD1 may be formed in the first recesses RS1, respectively. For example, the buffer layer BFL may be formed by a first SEG process using an inner surface of the first recess RS1 as a seed layer. The buffer layer BFL may be grown using the first to third semiconductor patterns SP1, SP2, and SP3 and the substrate 100, which are exposed through the first recess RS1, as a seed layer. As an example, the first SEG process may include a chemical vapor deposition (CVD) process or a molecular beam epitaxy (MBE) process.

The buffer layer BFL may contain a semiconductor material (e.g., SiGe) whose lattice constant is larger than that of a semiconductor material of the substrate 100. The buffer layer BFL may contain a relatively low concentration of germanium (Ge). In another embodiment, the buffer layer BFL may contain only silicon (Si), without germanium (Ge). A germanium concentration of the buffer layer BFL may range from 0 at % to 30 at %.

A second SEG process may be performed on the buffer layer BFL to form the main layer MAL. The main layer MAL may be formed to fill the first recess RS1 completely or nearly completely. The main layer MAL may contain a relatively high concentration of germanium. As an example, a germanium concentration of the main layer MAL may range from 30 at % to 70 at %.

In an embodiment, a third SEG process may be performed on the main layer MAL to form a capping layer. The capping layer may be formed of or include silicon (Si). A silicon concentration of the capping layer may range from 98 at % to 100 at %.

The first source/drain pattern SD1 may be doped in-situ with p-type impurities (e.g., boron, gallium, or indium) during the formation of the buffer and main layers BFL and MAL. Alternatively, impurities may be injected into the first source/drain pattern SD1, after the formation of the first source/drain pattern SD1.

The second source/drain patterns SD2 may be formed in the second recesses RS2, respectively. For example, the second source/drain pattern SD2 may be formed by a SEG process, in which an inner surface of the second recess RS2 is used as a seed layer. In an embodiment, the second source/drain pattern SD2 may be formed of or include the same semiconductor material (e.g., Si) as the substrate 100.

During the formation of the second source/drain pattern SD2, the second source/drain pattern SD2 may be doped in-situ with n-type impurities (e.g., phosphorus, arsenic, or antimony). Alternatively, impurities may be injected into the second source/drain pattern SD2, after the formation of the second source/drain pattern SD2.

In an embodiment, before the formation of the second source/drain pattern SD2, the inner spacer IP may be formed by replacing a portion of the second semiconductor layer SAL, which is exposed by the second recess RS2, with an insulating material. As a result, the inner spacers IP may be respectively formed between the second source/drain pattern SD2 and the second semiconductor layers SAL.

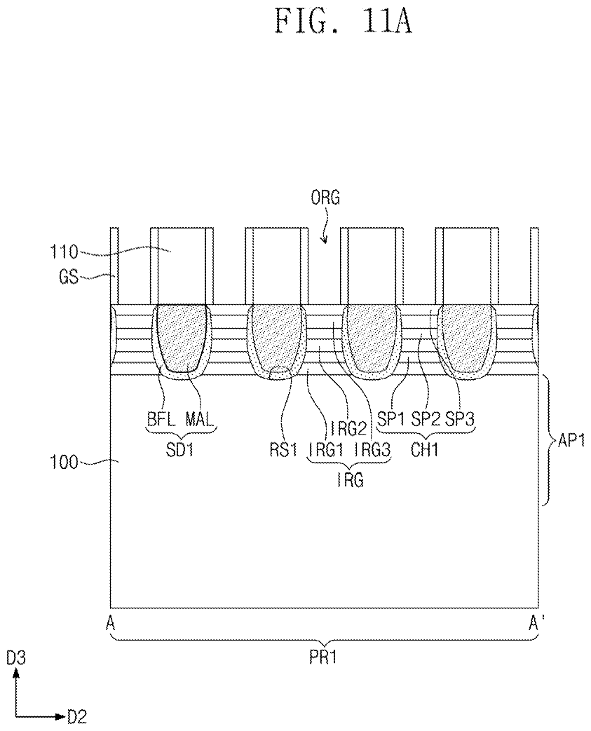

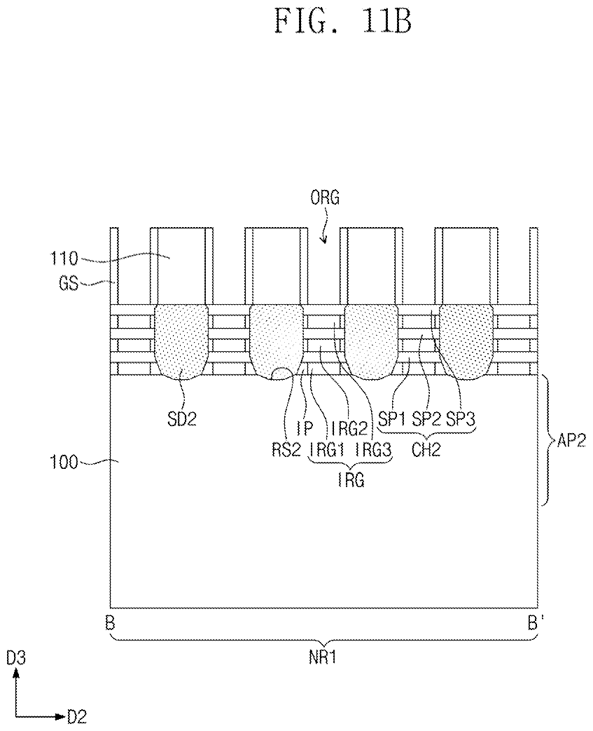

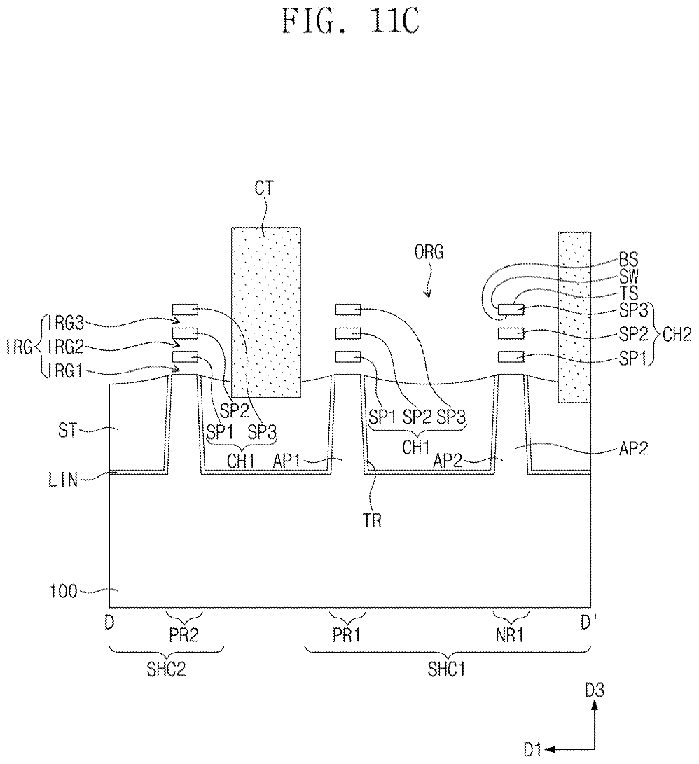

Referring to FIGS. 11A to 11C, the first interlayer insulating layer 110 may be formed on the first and second source/drain patterns SD1 and SD2, the hard mask patterns MP, and the gate spacers GS. In an embodiment, the first interlayer insulating layer 110 may include a silicon oxide layer.

The first interlayer insulating layer 110 may be planarized to expose top surfaces of the sacrificial patterns PP. The planarization of the first interlayer insulating layer 110 may be performed using an etch-back or chemical-mechanical polishing (CMP) process. All of the hard mask patterns MP may be removed during the planarization process. As a result, the first interlayer insulating layer 110 may be formed to have a top surface that is coplanar with the top surfaces of the sacrificial patterns PP and the top surfaces of the gate spacers GS.

A photolithography process may be performed to selectively open a region of the sacrificial pattern PP. For example, a region of the sacrificial pattern PP, which is located on a boundary between the first and second single height cells SHC1 and SHC2, may be selectively opened. The opened region of the sacrificial pattern PP may be selectively etched and removed. The gate cutting pattern CT may be formed by filling a space, which is formed by removing the sacrificial pattern PP, with an insulating material (e.g., see FIG. 11C).

In an embodiment, the exposed sacrificial patterns PP may be selectively removed. As a result of the removal of the sacrificial patterns PP, an outer region ORG may be formed to expose the first and second channel patterns CH1 and CH2 (e.g., see FIG. 11C). The removal of the sacrificial patterns PP may include a wet etching process which is performed using an etching solution capable of selectively etching polysilicon.

The second semiconductor layers SAL, which are exposed through the outer region ORG, may be selectively removed to form inner regions IRG (e.g., see FIG. 11C). For example, an etching process of selectively etching the second semiconductor layers SAL may be performed to leave the first to third semiconductor patterns SP1, SP2, and SP3 and to remove only the second semiconductor layers SAL. An etch recipe for the etching process may be chosen to etch a layer (e.g., a silicon germanium layer), which is formed to have a relatively high germanium concentration, at a high etch rate. For example, the etching process may be chosen to have a high etch rate to a silicon germanium layer whose germanium concentration is higher than 10 at %.

During the etching process, the second semiconductor layers SAL may be removed from the first and second PMOSFET regions PR1 and PR2 and the first and second NMOSFET regions NR1 and NR2. The etching process may be a wet etching process. An etchant material, which is used in the etching process, may be chosen to quickly remove the second semiconductor layer SAL having a relatively high germanium concentration. Meanwhile, the first source/drain patterns SD1 on the first and second PMOSFET regions PR1 and PR2 may be protected from the etching process by the buffer layer BFL having a relatively low germanium concentration.

Referring to FIG. 11C, as a result of the selective removal of the second semiconductor layers SAL, the stacked first to third semiconductor patterns SP1, SP2, and SP3 may be left on each of the first and second active patterns AP1 and AP2. Empty regions, which are formed by removing the second semiconductor layers SAL, may be used as first to third inner regions IRG1, IRG2, and IRG3, respectively.

For example, the first inner region IRG1 may be formed between the active pattern AP1 or AP2 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

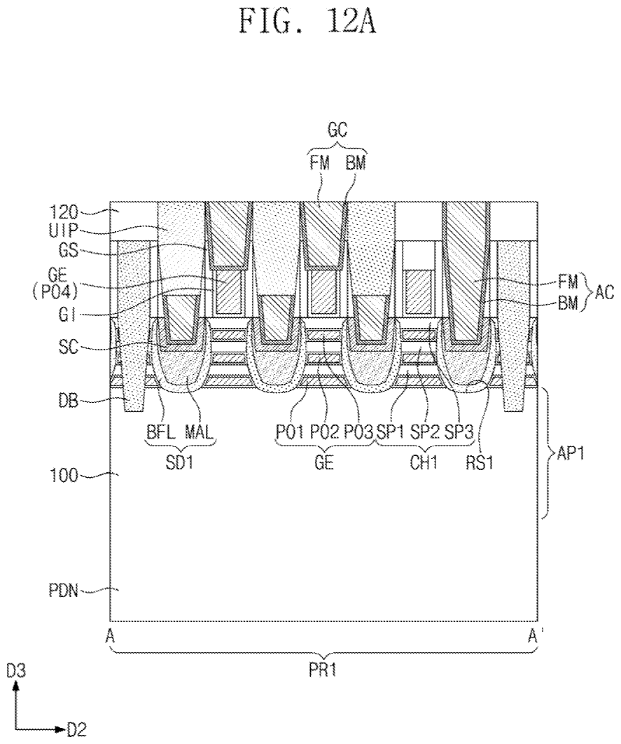

Referring to FIGS. 12A and 12D, the gate insulating layer GI may be conformally formed on the exposed first to third semiconductor patterns SP1, SP2, and SP3. The gate electrode GE may be formed on the gate insulating layer GI. The gate electrode GE may include the first to third inner electrodes PO1, PO2, and PO3, which are formed in the first to third inner regions IRG1, IRG2, and IRG3, and the outer electrode PO4, which is formed in the outer region ORG.

The gate electrode GE may be vertically recessed to have a reduced height. Upper portions of gate cutting patterns CT may be slightly recessed, during the recessing of the gate electrode GE. The gate capping pattern GP may be formed on the recessed gate electrode GE.

The division structure DB may be formed on boundary between the cells. The division structure DB may penetrate the gate capping pattern GP and the gate electrode GE and may be extended into the active pattern AP1 or AP2. The division structure DB may be formed of or include an insulating material (e.g., silicon oxide or silicon nitride). The second interlayer insulating layer 120 may be formed on the first interlayer insulating layer 110. The second interlayer insulating layer 120 may include a silicon oxide layer.

Referring to FIG. 13, contact holes CTH may be formed to penetrate the first and second interlayer insulating layers 110 and 120, the device isolation layer ST, and the insulating layer LIN and expose the substrate 100. For example, at least one of the contact holes CTH may be formed on a border between the first and second tab cells TC1 and TC2. The contact hole CTH may be formed between a pair of first active patterns AP1. As a distance to the bottom surface of the substrate 100 decreases, a width of the contact hole CTH may decrease.

FIG. 14 is an enlarged sectional view illustrating a portion ‘M’ of FIG. 13. Referring to FIG. 14, a bottom surface of the contact hole CTH may be lower than the top surface of the substrate 100. In the present specification, the top surface of the substrate 100 may mean a bottom of the trench TR. The contact hole CTH may expose an inner side surface IW of the substrate 100.

Referring to FIG. 15A, the protective capping pattern CAP may be formed in the substrate 100. The protective capping pattern CAP may enclose the exposed inner side surface IW of the substrate 100. For example, the protective capping pattern CAP may be formed by oxidizing the inner side surface IW of the substrate 100. That is, the protective capping pattern CAP may be formed of or include silicon oxide, because the protective capping pattern CAP is formed as a result of the oxidation of the inner side surface IW of the substrate 100 made of silicon (Si). For example, the protective capping pattern CAP may be formed of or include silicon oxide, for example, SiO₂.

Referring to FIG. 15B, a lower contact LCT may be formed to fill the contact hole CTH. More specifically, the lower contact LCT may be formed by filling the contact hole CTH with a metallic material. The lower contact LCT may include the protruding portion LP buried in the substrate 100 (e.g., see FIG. 6). The protective capping pattern CAP may enclose the bottom surface and the opposite side surfaces of the protruding portion LP. At least a portion of the side surface of the lower contact LCT may be in direct contact with the device isolation layer ST and the insulating layer LIN. As a distance to the bottom surface 100b of the substrate 100 decreases, a width of the lower contact LCT may decrease.

Thereafter, the active contacts AC may be formed to penetrate the second interlayer insulating layer 120 and the first interlayer insulating layer 110 to be electrically connected to the first and second source/drain patterns SD1 and SD2, as previously described with reference to FIG. 4 and FIGS. 5A to 5E. The gate contact GC may be formed to penetrate the second interlayer insulating layer 120 and the gate capping pattern GP to be electrically connected to the gate electrode GE. The third interlayer insulating layer 130 may be formed on the active contacts AC and the gate contacts GC. The first metal layer M1 may be formed in the third interlayer insulating layer 130. The first metal layer M1 may include the first to third power lines M1_R1, M1_R2, and M1_R3, which are electrically connected to the first to third penetration vias LCT1 to LCT3, respectively. The fourth interlayer insulating layer 140 may be formed on the third interlayer insulating layer 130. The second metal layer M2 may be formed in the fourth interlayer insulating layer 140.

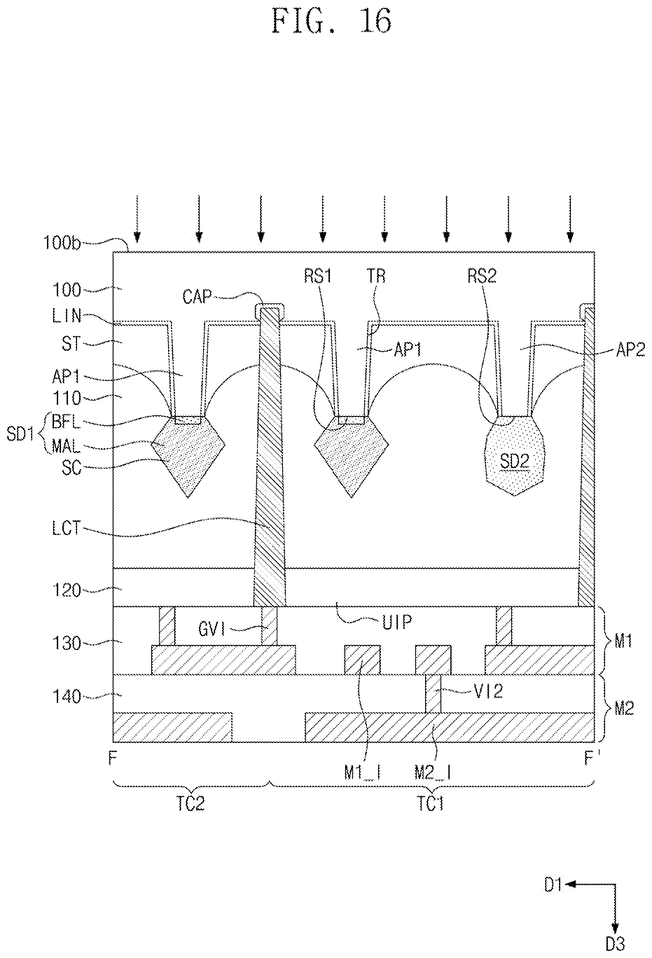

Referring to FIG. 16, after a back-end-of-line (BEOL) process, the substrate 100 may be flipped upside down such that the bottom surface 100b of the substrate 100 is exposed to the outside. A planarization process may be performed on the bottom surface 100b of the substrate 100 to reduce a thickness of the substrate 100.

Referring to FIG. 17, a patterning process may be performed on the bottom surface 100b of the substrate 100 to form an interconnection trench VPT. The interconnection trench VPT may expose the insulating layer LIN and the protective capping pattern CAP. The interconnection trench VPT may have a width in the first direction D1. As a distance to the bottom surface 100b of the substrate 100 decreases, the width may increase.

FIG. 18 is an enlarged sectional view illustrating a portion ‘M’ of FIG. 17. Referring to FIG. 18, the formation of the interconnection trench VPT may include a process of etching a portion of the substrate 100. The protective capping pattern CAP and the insulating layer LIN may not be removed by the etching process. Here, the protective capping pattern CAP may protect the lower contact LCT such that the lower contact LCT is not removed by the etching process. The insulating layer LIN may protect the device isolation layer ST such that the device isolation layer ST is not removed by the etching process.

Since the protective capping pattern CAP be formed on the lower contact LCT, the lower contact LCT may not be exposed to the outside. Thus, it may be possible to prevent properties of the lower contact LCT from being changed by the etching process. The protective capping pattern CAP may suppress the removal and/or oxidation of the lower contact LCT.

Referring to FIG. 19, the protective capping pattern CAP may be removed by an etching process. The etching process may be a wet etching process. The insulating layer LIN and the lower contact LCT may not be removed by the wet etching process. The insulating layer LIN may prevent the device isolation layer ST from being damaged by the wet etching process.

Referring to FIG. 6, the lower power structure LPW may be formed by filling the interconnection trench VPT with a conductive material. A top surface of the lower power structure LPW may be in direct contact with the insulating layer LIN. The lower power structure LPW may enclose the protruding portion LP of the lower contact LCT2. As a distance to the bottom surface 100b of the substrate 100 decreases, a width of the lower power structure LPW may increase.

Thereafter, the power delivery network layer PDN may be formed on the bottom surface 100b of the substrate 100. The power delivery network layer PDN may be formed such that the source or drain voltage is applied to the first to third power lines M1_R1, M1_R2, and M1_R3.

Hereinafter, other embodiments will be described. For concise description, an element previously described with reference to FIG. 4 and FIGS. 5A to 5E may be identified by the same reference number without repeating an overlapping description thereof.

FIGS. 20A and 20B are sectional views, which are respectively taken along the lines C-C′ and D-D′ of FIG. 4 to illustrate a semiconductor device according to an embodiment.

Referring to FIGS. 4, 20A, and 20B, first to third lower power structures VPR1, VPR2, and VPR3 may be provided in a lower portion of the substrate 100. The first to third lower power structures VPR1, VPR2, and VPR3 may be extended in the second direction D2 to be parallel to each other. The first lower power structure VPR1 may be a conduction path, to which the first voltage VSS (e.g., a ground voltage) is provided. The second lower power structure VPR2 may be a conduction path, to which the second voltage VDD (e.g., a power voltage) is provided. According to an embodiment, the substrate 100 may be replaced by a backside isolation structure formed of a material such as silicon oxide before the first to third lower power structures VPR1, VPR2 and VPR3 are formed so that these lower power structures and the lower contact LCT are connected to each other in the backside isolation structure. For example, when the semiconductor device in the present embodiments is completed, the substrate 100 may have been replaced by the backside isolation structure to better isolate the lower power structures from each other or other circuit elements.

The first lower power structure VPR1 may be disposed on a fourth border BD4 of the first single height cell SHC1. The second lower power structure VPR2 may be disposed on a third border BD3 of the first single height cell SHC1. In other words, the first single height cell SHC1 may be defined between the first lower power structure VPR1 and the second lower power structure VPR2. The second single height cell SHC2 may be defined between the second lower power structure VPR2 and the third lower power structure VPR3.

Referring to FIGS. 20A and 20B, the second lower power structure VPR2 may be electrically connected to the lower contact LCT. The lower contact LCT may electrically connect the second lower power structure VPR2 to the active contact AC. More specifically, the lower contact LCT may be directly coupled to the active contact AC. A lower power structure VPR1-VPR3 may be electrically connected to the source/drain pattern SD1 or SD2 through the lower contact LCT and the active contact AC.

The lower contact LCT and the lower power structure VPR1-VPR3 may include the same metallic materials or may include different metallic materials from each other. For example, the lower power structure VPR1-VPR3 may be formed of or include at least one selected from the group consisting of cobalt, molybdenum, and tungsten. The lower contact LCT may be formed of or include at least one selected from the group consisting of cobalt, molybdenum, and tungsten. In an embodiment, a lower portion of the lower contact LCT may be enclosed by the lower power structure VPR1-VPR3.

According to an embodiment, a power line, which is used to supply a power to the single height cell SHC, may be provided in the form of the lower power structure VPR1-VPR3 and may be buried in the substrate 100. Accordingly, a power line in the first metal layer M1 may be omitted. The first interconnection lines M1_I for signal transmission may be disposed in the first metal layer M1.

According to an embodiment, a semiconductor device may include a lower contact, which is provided to penetrate a device isolation layer, and a lower power structure, which is connected to the lower contact, and an insulating layer may be interposed between the lower power structure and the device isolation layer. Thus, it may be possible to prevent the device isolation layer from being removed in a subsequent step of forming a protective capping pattern.

According to an embodiment, a semiconductor fabrication method may include forming the protective capping pattern on the lower contact. Due to the protective capping pattern, it may be possible to prevent the lower contact from being damaged by an etching process for forming the lower power structure. As a result, it may be possible to fabricate a semiconductor device with improved electrical characteristics, reduced defect ratio, and increased production yield.

While example embodiments have been particularly shown and described, it will be understood by one of ordinary skill in the art that variations in form and detail may be made therein without departing from the spirit and scope of the attached claims.

What is claimed is:

1. A semiconductor device, comprising:
a substrate comprising an active pattern;
a source/drain pattern on the active pattern;
a device isolation layer at a lateral side of the active pattern;
a lower power structure below a top surface of the substrate;
an insulating layer on the top surface of the substrate;
a lower contact penetrating the device isolation layer and connecting the source/drain pattern to the lower power structure; and
a power delivery network layer below the top surface of the substrate,
wherein the lower power structure comprises a connecting portion connected to the lower contact,
wherein the lower contact comprises a protruding portion buried in the connecting portion, and
wherein the insulating layer is disposed between the connecting portion and the device isolation layer.

2. The semiconductor device of claim 1,
wherein a top surface of the connecting portion is in direct contact with the insulating layer.

3. The semiconductor device of claim 1, wherein the connecting portion encloses a bottom surface and opposite side surfaces of the protruding portion.

4. The semiconductor device of claim 1, further comprising a metal layer comprising an interconnection metal line, above the source/drain pattern,
wherein the lower contact is connected to the source/drain pattern through the interconnection metal line.

5. The semiconductor device of claim 1,
wherein at least a portion of a side surface of the lower contact is in contact with the insulating layer.

6. The semiconductor device of claim 1, wherein as a distance to a bottom surface of the power delivery network layer decreases, a width of the lower contact decreases.

7. The semiconductor device of claim 1, wherein the power delivery network layer is configured to apply a power voltage to the lower power structure.

8. A method of manufacturing a semiconductor device, comprising:
forming an active pattern on a substrate;
forming an insulating layer on the substrate and the active pattern;
forming a device isolation layer at a side of the active pattern;
forming a source/drain pattern on the active pattern, and a interlayer insulating layer on the source/drain pattern;
forming a contact hole, which is vertically extended from the interlayer insulating layer to the substrate to expose an inner side surface of the substrate;
oxidizing the inner side surface of the substrate to form a protective capping pattern;
filling the contact hole with a metallic material to form a lower contact;
performing a patterning process on a bottom surface of the substrate to form an interconnection trench exposing the lower contact;
removing the protective capping pattern; and
filling the interconnection trench with a conductive material to form a lower power structure.

9. The method of claim 8,
wherein the lower power structure comprises a connecting portion connected to the lower contact,
wherein the lower contact comprises a protruding portion buried in the connecting portion,
wherein the insulating layer is disposed between the connecting portion and the device isolation layer, and
wherein a top surface of the connecting portion is in direct contact with the insulating layer.

10. The method of claim 8, wherein the protective capping pattern comprises silicon oxide.

11. The method of claim 8,
wherein the forming the interconnection trench is performed in such a way that the protective capping pattern and the insulating layer are not removed.

12. The method of claim 8,
wherein the removing the protective capping pattern is performed in such a way that the insulating layer and the lower contact are not removed.

13. The method of claim 9, wherein the protective capping pattern encloses the protruding portion.

14. The method of claim 8, wherein as a distance to the bottom surface of the substrate decreases, a width of the lower contact decreases.

15. The method of claim 8,
wherein the insulating layer comprises at least one of silicon oxide and silicon nitride.

16. A semiconductor device, comprising:
a substrate comprising an active pattern;
a device isolation layer at a lateral side of the active pattern;
an insulating layer between the substrate and the device isolation layer;
a channel pattern and a source/drain pattern on the active pattern;
a gate electrode on the channel pattern;
a gate insulating layer between the gate electrode and the channel pattern;
a gate spacer on a side surface of the gate electrode;
a gate capping pattern on a top surface of the gate electrode;
an interlayer insulating layer isolating the source/drain pattern and the gate capping pattern;
an active contact provided to penetrate the interlayer insulating layer, and electrically connected to the source/drain pattern;
a metal-semiconductor compound layer between the active contact and the source/drain pattern;
a gate contact provided to penetrate the interlayer insulating layer and the gate capping pattern, and electrically connected to the gate electrode;
a first metal layer on the interlayer insulating layer, the first metal layer comprising an interconnection line electrically connected to the active contact;
a second metal layer on the first metal layer, the second metal layer comprising a second interconnection line electrically connected to the first metal layer;
a lower power structure in the substrate;
a lower contact and extended into the substrate at a lateral side of the source/drain pattern, the lower contact connecting the active contact to the lower power structure; and
a power delivery network layer below a top surface of the substrate,
wherein the lower contact comprises a lower portion inserted in the lower power structure, and
wherein a top surface of the lower power line is in a direct contact with the insulating layer.

17. The semiconductor device of claim 16,
wherein the insulating layer is disposed between the lower contact and the device isolation layer.

18. The semiconductor device of claim 16, further comprising a metal layer comprising an interconnection metal line, above the source/drain pattern,
wherein the lower contact is connected to the source/drain pattern through the interconnection metal line.

19. The semiconductor device of claim 16,
wherein at least a portion of a side surface of the lower contact is in contact with the insulating layer.

20. The semiconductor device of claim 16, wherein as a distance to a bottom surface of the substrate decreases, a width of the lower contact decreases.
